(19) United States
(12) Patent Application Publication
(10) Pub. No.: US 2024/0194777 A1
(43) Pub. Date: Jun. 13, 2024

(54) SEMICONDUCTOR DEVICE

(71) Applicant: FUJI ELECTRIC CO., LTD., Kanagawa (JP)

(72) Inventors: Atsushi SHOJI, Matsumoto-city (JP); Motoyoshi KUBOUCHI, Matsumoto-city (JP)

(21) Appl. No.: 18/582,651

(22) Filed: Feb. 21, 2024

Related U.S. Application Data
(63) Continuation of application No. PCT/JP2023/010179, filed on Mar. 15, 2023.

(30) Foreign Application Priority Data
Mar. 16, 2022 (JP) 2022-041046

(51) Int. Cl. H01L 29/78; H01L 29/06

(52) U.S. Cl. CPC H01L 29/7804; H01L 29/0615; H01L 29/7813

(57) ABSTRACT

Provided is a semiconductor device including: a semiconductor substrate having a base region of a second conductivity type provided between a drift region and an upper surface of the semiconductor substrate; a first lifetime region arranged in the drift region on a lower surface side of the semiconductor substrate relative to the base region; and a second lifetime region which is arranged to be sandwiched between first lifetime regions including the first lifetime region in a first direction parallel to the upper surface of the semiconductor substrate and in which a carrier lifetime is longer than in the first lifetime region, where a width of the second lifetime region in the first direction is 0.2 times or more a thickness of the first lifetime region in a second direction perpendicular to the upper surface of the semiconductor substrate.

The contents of the following patent application(s) are incorporated herein by reference:

NO. 2022-041046 filed in JP on Mar. 16, 2022

NO. PCT/JP2023/010179 filed in WO on Mar. 15, 2023

### BACKGROUND

### 1. Technical Field

The present invention relates to a semiconductor device.

### 2. Related Art

Conventionally, in a semiconductor device including a freewheeling diode (FWD) or the like, there is a known technology for forming lattice defects in the semiconductor substrate to adjust a carrier lifetime (see Patent Documents 1 and 2, for example).

Patent Document 1: Japanese Patent Application Publication No. 2020-31155

Patent Document 2: Japanese Patent Application Publication No. 2020-120121

### BRIEF DESCRIPTION OF THE DRAWINGS

FIG. 1 illustrates a top view showing an example of a semiconductor device 100 according to one embodiment of the present invention.

FIG. 2 illustrates an enlarged view of a region D in FIG. 1.

FIG. 3 illustrates an example of a cross section e-e in FIG. 2.

FIG. 4 illustrates examples of V-I characteristics during forward conduction of a diode portion 80 according to a comparative example.

FIG. 5 illustrates an arrangement example of a first lifetime region 204 and a second lifetime region 200 in a diode portion 80.

FIG. 6 illustrates an enlarged cross sectional view in the vicinity of a second lifetime region 200.

FIG. 7 illustrates distribution examples of carrier lifetimes, vacancy densities, and helium chemical concentrations on a line f-f in FIG. 6.

FIG. 8 illustrates distribution examples of carrier lifetimes, vacancy densities, and helium chemical concentrations on a line g-g in FIG. 6.

FIG. 9 illustrates distribution examples of carrier lifetimes, vacancy densities, and helium chemical concentrations on a line h-h in FIG. 6.

FIG. 10 illustrates another example of an enlarged cross sectional view in the vicinity of a second lifetime region 200.

FIG. 11A shows each of a distribution diagram of a net doping concentration (A), a distribution diagram of a hydrogen chemical concentration (B), a distribution diagram of a lattice defect density (C), a distribution diagram of a carrier lifetime (D), a distribution diagram of carrier mobility (E), and a distribution diagram of a carrier concentration (F) along a line h-h in a semiconductor device 100 according to the embodiment example shown in FIG. 10.

FIG. 11B illustrates another example of an enlarged cross sectional view in the vicinity of a second lifetime region 200.

FIG. 11C shows each of a distribution diagram of a net doping concentration (A), a distribution diagram of a hydrogen chemical concentration (B), a distribution diagram of a lattice defect density (C), a distribution diagram of a carrier lifetime (D), a distribution diagram of carrier mobility (E), and a distribution diagram of a carrier concentration (F) along a line h-h in a semiconductor device 100 according to the embodiment example shown in FIG. 11B.

FIG. 11D illustrates another example of an enlarged cross sectional view in the vicinity of a second lifetime region 200.

FIG. 12 illustrates examples of V-I characteristics during forward conduction of a diode portion 80.

FIG. 13 illustrates trade-off characteristics between a forward voltage Vf and a reverse recovery loss Err in a diode portion 80.

FIG. 14 illustrates a relationship between a width W1 of a second lifetime region 200 and a snapback amount (an SB amount).

FIG. 15 illustrates whether snapback has occurred when a thickness T1 of a first lifetime region 204 and a width W1 of a second lifetime region 200 are changed.

FIG. 16A illustrates another arrangement example of a first lifetime region 204 and a second lifetime region 200 in a diode portion 80.

FIG. 16B illustrates another arrangement example of a first lifetime region 204 and a second lifetime region 200 in a diode portion 80.

FIG. 16C illustrates another arrangement example of a first lifetime region 204 and a second lifetime region 200 in a diode portion 80.

FIG. 17 illustrates whether snapback has occurred when the number of second lifetime regions 200 included in one diode portion 80 and a width W1 of each of the second lifetime regions 200 are changed.

FIG. 18 illustrates an arrangement example of a first lifetime region 204 and a second lifetime region 200 in an XY plane.

FIG. 19 illustrates another arrangement example of a first lifetime region 204 and a second lifetime region 200 in an XY plane.

FIG. 20 illustrates another arrangement example of a first lifetime region 204 and a second lifetime region 200 in an XY plane.

FIG. 21 illustrates another arrangement example of a first lifetime region 204 and a second lifetime region 200 in an XY plane.

FIG. 22A illustrates another arrangement example of a first lifetime region 204 and a second lifetime region 200 in an XY plane.

FIG. 22B illustrates another arrangement example of a first lifetime region 204 and a second lifetime region 200 in an XY plane.

FIG. 23A illustrates another arrangement example of a first lifetime region 204 and a second lifetime region 200 in an XY plane. FIG. 23B illustrates another arrangement example of a first lifetime region 204 and a second lifetime region 200 in an XY plane.

FIG. 24 illustrates another arrangement example of a first lifetime region 204 and a second lifetime region 200 in an XY plane.

FIG. 25 illustrates another arrangement example of a first lifetime region 204 and a second lifetime region 200 in an XY plane.

FIG. 26 illustrates another arrangement example of a first lifetime region 204 and a second lifetime region 200 in an XY plane.

### DESCRIPTION OF EXEMPLARY EMBODIMENTS

Hereinafter, the present invention will be described through embodiments of the invention, but the following embodiments do not limit the invention according to claims. In addition, not all of the combinations of features described in the embodiments are essential to the solution of the invention.

In the present specification, one side in a direction parallel to a depth direction of a semiconductor substrate is referred to as “upper” and another side is referred to as “lower”. One surface of two principal surfaces of a substrate, a layer or another member is referred to as an upper surface, and another surface is referred to as a lower surface. “Upper” and “lower” directions are not limited to a direction of gravity, or a direction in which a semiconductor device is mounted.

In the present specification, technical matters may be described using orthogonal coordinate axes of an X axis, a Y axis, and a Z axis. The orthogonal coordinate axes merely specify relative positions of components, and do not limit a specific direction. For example, the Z axis is not limited to indicate the height direction with respect to the ground. It should be noted that a +Z axis direction and a −Z axis direction are directions opposite to each other. When the Z axis direction is described without describing a positive or negative sign, it means that the direction is parallel to the +Z axis and the −Z axis.

In the present specification, orthogonal axes parallel to the upper surface and the lower surface of the semiconductor substrate are referred to as the X axis and the Y axis. In addition, an axis perpendicular to the upper surface and the lower surface of the semiconductor substrate is referred to as the Z axis. In the present specification, the direction of the Z axis may be referred to as the depth direction. In addition, in the present specification, a direction parallel to the upper surface and the lower surface of the semiconductor substrate may be referred to as a horizontal direction, including an X axis direction and a Y axis direction.

A region from a center of the semiconductor substrate in the depth direction to the upper surface of the semiconductor substrate may be referred to as an upper surface side. Similarly, a region from the center of the semiconductor substrate in the depth direction to the lower surface of the semiconductor substrate may be referred to as a lower surface side.

In the present specification, a case where a term such as “same” or “equal” is mentioned may include a case where an error due to a variation in manufacturing or the like is included. The error is, for example, within 10%.

In the present specification, a conductivity type of a doping region where doping has been carried out with an impurity is described as a P type or an N type. In the present specification, the impurity may particularly mean either a donor of the N type or an acceptor of the P type, and may be described as a dopant. In the present specification, doping means introducing the donor or the acceptor into the semiconductor substrate and turning it into a semiconductor presenting a conductivity type of the N type, or a semiconductor presenting conductivity type of the P type.

In the present specification, a doping concentration means a concentration of the donor or a concentration of the acceptor in a thermal equilibrium state. In the present specification, a net doping concentration means a net concentration obtained by adding the donor concentration set as a positive ion concentration to the acceptor concentration set as a negative ion concentration, taking into account of polarities of charges. As an example, when the donor concentration is N_{D} and the acceptor concentration is N_{A}, the net doping concentration at any position is given as N_{D}−N_{A}. In the present specification, the net doping concentration may be simply described as the doping concentration.

The donor has a function of supplying electrons to a semiconductor. The acceptor has a function of receiving electrons from the semiconductor. The donor and the acceptor are not limited to the impurities themselves. For example, a VOH defect in which a vacancy (V), oxygen (O), and hydrogen (H) present in the semiconductor are attached together functions as the donor which supplies electrons. In the present specification, the VOH defect may be referred to as a hydrogen donor.

In the semiconductor substrate in the present specification, bulk donors of the N type are distributed throughout. A bulk donor is a dopant donor substantially uniformly contained in an ingot during the manufacture of the ingot from which the semiconductor substrate is made. The bulk donor in this example is an element other than hydrogen. The bulk donor dopant is, but not limited to, for example, phosphorous, antimony, arsenic, selenium, or sulfur. The bulk donor in this example is phosphorous. The bulk donor is contained also in a region of the P type. The semiconductor substrate may be a wafer cut out from a semiconductor ingot, or may be a chip obtained by singulating the wafer. The semiconductor ingot may be manufactured by any of a Czochralski method (CZ method), a magnetic field applied Czochralski method (MCZ method), or a float zone method (FZ method). The ingot in this example is manufactured by the MCZ method. A concentration of oxygen contained in the substrate manufactured by the MCZ method is 1×10¹⁷ to 7×10¹⁷/cm³. The concentration of oxygen contained in the substrate manufactured by the FZ method is 1×10¹⁵ to 5×10¹⁶/cm³. When the concentration of oxygen is higher, hydrogen donors tend to be more easily generated. As a bulk donor concentration, a chemical concentration of the bulk donors distributed throughout the semiconductor substrate may be used, and the bulk donor concentration may have a value between 90% and 100% of the chemical concentration. In addition, as the semiconductor substrate, a non-doped substrate not containing a dopant such as phosphorous may be used. In that case, a bulk donor concentration (D0) of the non-doped substrate is, for example, 1×10¹⁰/cm³ or greater and 5×10¹²/cm³ or smaller. The bulk donor concentration (D0) of the non-doped substrate is preferably 1×10¹¹/cm³ or greater. The bulk donor concentration (D0) of the non-doped substrate is preferably 5×10¹²/cm³ or smaller. It should be noted that each concentration in the present invention may have a value at a room temperature. As the value at a room temperature, a value at 300K (Kelvin) (about 26.9 degrees C.) as an example may be used.

In the present specification, a description of a P+ type or an N+ type means a higher doping concentration than that of the P type or the N type, and a description of a P− type or an N− type means a lower doping concentration than that of the P type or the N type. In addition, in the present specification, a description of a P++ type or an N++ type means a higher doping concentration than that of the P+ type or the N+ type. In the present specification, a unit system is an SI unit system unless otherwise noted. Although a unit of a length may be expressed in cm, various calculations may be performed after conversion to meters (m).

A chemical concentration in the present specification refers to an atomic density of an impurity measured regardless of an electrical activation state. The chemical concentration can be measured by, for example, secondary ion mass spectrometry (SIMS). The net doping concentration described above can be measured by capacitance-voltage profiling (CV method). In addition, a carrier concentration measured by spreading resistance profiling (SRP method) may be set as the net doping concentration. The carrier concentration measured by the CV method or the SRP method may be a value in a thermal equilibrium state. In addition, in a region of the N type, the donor concentration is sufficiently greater than the acceptor concentration, and thus the carrier concentration in the region may be defined as the donor concentration. Similarly, in a region of the P type, the carrier concentration in the region may be defined as the acceptor concentration. In the present specification, the doping concentration in the N type region may be referred to as the donor concentration, and the doping concentration in the P type region may be referred to as the acceptor concentration.

When a concentration distribution of the donor, acceptor, or net doping has a peak in a region, a value of the peak may be set as the concentration of the donor, acceptor, or net doping in the region. In a case where the concentration of the donor, acceptor or net doping is substantially uniform in a region, or the like, an average value of the concentration of the donor, acceptor or net doping in the region may be set as the concentration of the donor, acceptor or net doping. In the present specification, atoms/cm³ or /cm³ is used to express a concentration per unit volume. This unit is used for the donor or acceptor concentration or the chemical concentration in the semiconductor substrate. A notation of atoms may be omitted.

The carrier concentration measured by the SRP method may be lower than the concentration of the donor or the acceptor. In a range where a current flows when a spreading resistance is measured, carrier mobility of the semiconductor substrate may be lower than a value in a crystalline state. The decrease in carrier mobility occurs when carriers are scattered due to disorder (disorder) of a crystal structure due to lattice defects or the like.

The concentration of the donor or the acceptor calculated from the carrier concentration measured by the CV method or the SRP method may be lower than a chemical concentration of an element indicating the donor or the acceptor. As an example, in a silicon semiconductor, a donor concentration of phosphorous or arsenic serving as a donor, or an acceptor concentration of boron (boron) serving as an acceptor is approximately 99% of chemical concentrations of these. On the other hand, in the silicon semiconductor, a donor concentration of hydrogen serving as a donor is approximately 0.1% to 10% of a chemical concentration of hydrogen.

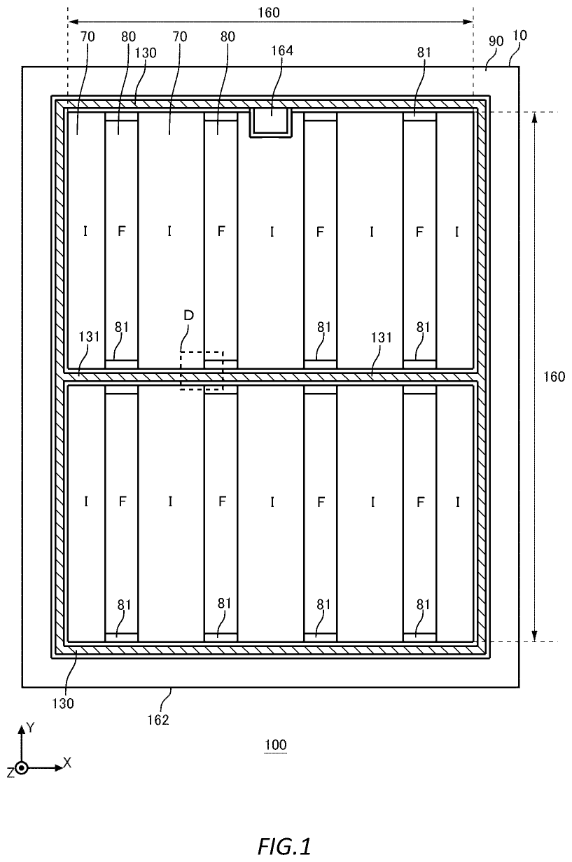

FIG. 1 illustrates a top view showing an example of a semiconductor device 100 according to one embodiment of the present invention. FIG. 1 shows a position at which each member is projected on an upper surface of a semiconductor substrate 10. FIG. 1 shows only some members of the semiconductor device 100, and illustration of some members is omitted.

The semiconductor device 100 includes the semiconductor substrate 10. The semiconductor substrate 10 is a substrate that is formed of a semiconductor material. As an example, the semiconductor substrate 10 is a silicon substrate. The semiconductor substrate 10 has end sides 162 in a top view. When simply referred to as the top view in the present specification, it means that the semiconductor substrate 10 is viewed from an upper surface side. The semiconductor substrate 10 in this example has two sets of end sides 162 opposite to each other in a top view. In FIG. 1, the X axis and the Y axis are parallel to any of the end sides 162. In addition, the Z axis is perpendicular to the upper surface of the semiconductor substrate 10.

The semiconductor substrate 10 is provided with an active portion 160. The active portion 160 is a region where a main current flows in a depth direction between the upper surface and a lower surface of the semiconductor substrate 10 when the semiconductor device 100 operates. An emitter electrode is provided above the active portion 160, but illustration thereof is omitted in FIG. 1. The active portion 160 may refer to a region that overlaps with the emitter electrode in a top view. In addition, a region sandwiched between active portions 160 in a top view may also be included in the active portion 160.

The active portion 160 is provided with transistor portions 70 including transistor elements such as an Insulated Gate Bipolar Transistor (IGBT). The active portion 160 may be further provided with diode portions 80 including diode elements such as a freewheeling diode (FWD). In the example shown in FIG. 1, the transistor portions 70 and the diode portions 80 are alternately arranged along a predetermined array direction (the X axis direction in this example) at the upper surface of the semiconductor substrate 10. The semiconductor device 100 in this example is a reverse-conducting IGBT (RC-IGBT).

In FIG. 1, a region where a transistor portion 70 is arranged is marked with a symbol “I”, and a region where a diode portion 80 is arranged is marked with a symbol “F”. In the present specification, a direction perpendicular to the array direction in a top view may be referred to as an extending direction (the Y axis direction in FIG. 1). The transistor portion 70 and the diode portion 80 may each have a longitudinal length in the extending direction. In other words, a length of the transistor portion 70 in the Y axis direction is greater than a width in the X axis direction. Similarly, a length of the diode portion 80 in the Y axis direction is greater than a width in the X axis direction. The extending direction of the transistor portion 70 and the diode portion 80 may be the same as a longitudinal direction of each trench portion described below.

The diode portion 80 has a cathode region of the N+ type in a region in contact with the lower surface of the semiconductor substrate 10. In the present specification, a region where the cathode region is provided is referred to as the diode portion 80. In other words, the diode portion 80 is a region that overlaps with the cathode region in a top view. At the lower surface of the semiconductor substrate 10, a collector region of the P+ type may be provided in a region other than the cathode region. In the present specification, the diode portion 80 may also include an extension region 81 where the diode portion 80 extends to a gate runner described below in the Y axis direction. The collector region is provided at a lower surface of the extension region 81.

The transistor portion 70 has the collector region of the P+ type in a region in contact with the lower surface of the semiconductor substrate 10. In addition, in the transistor portion 70, an emitter region of the N type, a base region of the P type, and a gate structure having a gate conductive portion and a gate dielectric film are periodically arranged on the upper surface side of the semiconductor substrate 10.

The semiconductor device 100 may have one or more pads above the semiconductor substrate 10. The semiconductor device 100 in this example has a gate pad 164. The semiconductor device 100 may have a pad such as an anode pad, a cathode pad, and a current detection pad. Each pad is arranged in the vicinity of an end side 162. The vicinity of the end side 162 refers to a region between the end side 162 and the emitter electrode in a top view. When the semiconductor device 100 is mounted, each pad may be connected to an external circuit via a wiring line such as a wire.

A gate potential is applied to the gate pad 164. The gate pad 164 is electrically connected to a conductive portion of a gate trench portion of the active portion 160. The semiconductor device 100 includes a gate runner that connects the gate pad 164 and the gate trench portion. In FIG. 1, the gate runner is hatched with diagonal lines.

The gate runner in this example has outer circumferential gate runners 130 and an active-side gate runner 131. The outer circumferential gate runners 130 are arranged between the active portion 160 and the end sides 162 of the semiconductor substrate 10 in a top view. The outer circumferential gate runners 130 in this example enclose the active portion 160 in a top view. A region enclosed by the outer circumferential gate runners 130 in a top view may be the active portion 160. In addition, a well region is formed below the gate runner. The well region is a P type region having a higher concentration than the base region described below, and is formed up to a position deeper than a position of the base region from the upper surface of the semiconductor substrate 10. A region enclosed by the well region in a top view may be the active portion 160.

An outer circumferential gate runner 130 is connected to the gate pad 164. The outer circumferential gate runners 130 are arranged above the semiconductor substrate 10. The outer circumferential gate runners 130 may be metal wiring lines containing aluminum or the like.

The active-side gate runner 131 is provided in the active portion 160. Providing the active-side gate runner 131 in the active portion 160 can reduce a variation in wiring line length from the gate pad 164 for each region of the semiconductor substrate 10.

The outer circumferential gate runners 130 and the active-side gate runner 131 are connected to the gate trench portion of the active portion 160. The outer circumferential gate runners 130 and the active-side gate runner 131 are arranged above the semiconductor substrate 10. The outer circumferential gate runners 130 and the active-side gate runner 131 may be wiring lines formed of a semiconductor such as polysilicon doped with an impurity.

The active-side gate runner 131 may be connected to the outer circumferential gate runners 130. The active-side gate runner 131 in this example is provided extending in the X axis direction so as to cross the active portion 160 substantially at a center of the Y axis direction, from one of the outer circumferential gate runners 130 sandwiching the active portion 160 to another. When the active portion 160 is divided by the active-side gate runner 131, the transistor portions 70 and the diode portions 80 may be alternately arranged in the X axis direction in each region obtained by the division.

The semiconductor device 100 may include a temperature sensing portion (not shown) which is a PN junction diode formed of polysilicon or the like, and a current detection portion (not shown) which simulates an operation of a transistor portion provided in the active portion 160.

The semiconductor device 100 in this example includes an edge termination structure portion 90 between the active portion 160 and the end sides 162 in a top view. The edge termination structure portion 90 in this example is arranged between the outer circumferential gate runners 130 and the end sides 162. The edge termination structure portion 90 reduces an electric field strength on the upper surface side of the semiconductor substrate 10. The edge termination structure portion 90 may include at least one of a guard ring, a field plate, or a RESURF which are annularly provided enclosing the active portion 160.

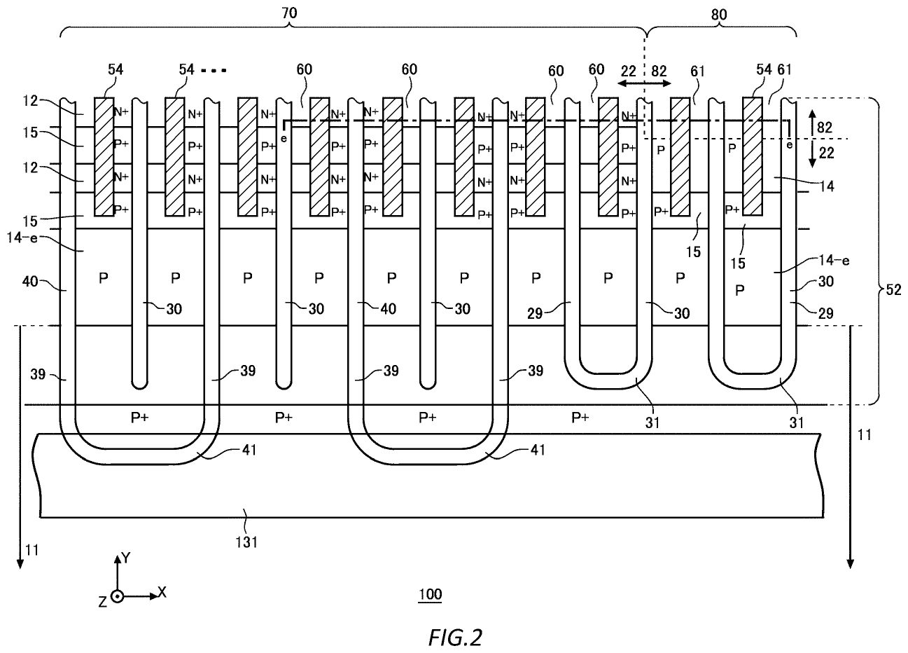

FIG. 2 illustrates an enlarged view of a region D in FIG. 1. The region D is a region including a transistor portion 70, a diode portion 80, and an active-side gate runner 131. A semiconductor device 100 in this example includes gate trench portions 40, dummy trench portions 30, a well region 11, emitter regions 12, base regions 14, and contact regions 15 which are provided inside on an upper surface side of a semiconductor substrate 10. A gate trench portion 40 and a dummy trench portion 30 are each an example of a trench portion. In addition, the semiconductor device 100 in this example includes an emitter electrode 52 and the active-side gate runner 131 which are provided above an upper surface of the semiconductor substrate 10. The emitter electrode 52 and the active-side gate runner 131 are provided separately from each other.

An interlayer dielectric film is provided between the emitter electrode 52 and the active-side gate runner 131, and the upper surface of the semiconductor substrate 10, but illustration thereof is omitted in FIG. 2. In the interlayer dielectric film in this example, contact holes 54 are provided penetrating the interlayer dielectric film. In FIG. 2, each of the contact holes 54 is hatched with diagonal lines.

The emitter electrode 52 is provided above the gate trench portions 40, the dummy trench portions 30, the well region 11, the emitter regions 12, the base regions 14, and the contact regions 15. The emitter electrode 52 is in contact with the emitter regions 12, the contact regions 15, and the base regions 14 at the upper surface of the semiconductor substrate 10, through the contact holes 54. In addition, the emitter electrode 52 is connected to dummy conductive portions in the dummy trench portions 30 through the contact holes provided in the interlayer dielectric film. The emitter electrode 52 may be connected to the dummy conductive portions of the dummy trench portions 30 at edges of the dummy trench portions 30 in the Y axis direction. The dummy conductive portions of the dummy trench portions 30 may not be connected to the emitter electrode 52 and a gate conductive portion, and may be controlled to be at a potential different from a potential of the emitter electrode 52 and a potential of the gate conductive portion.

The active-side gate runner 131 is connected to the gate trench portions 40 through the contact holes provided in the interlayer dielectric film. The active-side gate runner 131 may be connected to gate conductive portions of the gate trench portions 40 at edge portions 41 of the gate trench portions 40 in the Y axis direction. The active-side gate runner 131 is not connected to the dummy conductive portions in the dummy trench portions 30.

The emitter electrode 52 is formed of a material containing a metal. FIG. 2 shows a range where the emitter electrode 52 is provided. For example, at least a partial region of the emitter electrode 52 is formed of aluminum or an aluminum-silicon alloy, for example, a metal alloy such as AlSi or AlSiCu. The emitter electrode 52 may have a barrier metal formed of titanium, a titanium compound, or the like below a region formed of aluminum or the like. Further, a plug, which is formed by embedding tungsten or the like so as to be in contact with the barrier metal and aluminum or the like, may be included in a contact hole.

The well region 11 is provided overlapping the active-side gate runner 131. The well region 11 is provided extending with a predetermined width also in a range not overlapping the active-side gate runner 131. The well region 11 in this example is provided away from ends of the contact holes 54 in the Y axis direction on an active-side gate runner 131 side. The well region 11 is a region of a second conductivity type having a higher doping concentration than a base region 14. The base region 14 in this example is of the P− type, and the well region 11 is of the P+ type.

Each of the transistor portion 70 and the diode portion 80 has a plurality of trench portions arrayed in an array direction. In the transistor portion 70 in this example, one or more gate trench portions 40 and one or more dummy trench portions 30 are alternately provided along the array direction. In the diode portion 80 in this example, a plurality of dummy trench portions 30 are provided along the array direction. In the diode portion 80 in this example, the gate trench portion 40 is not provided.

The gate trench portion 40 in this example may have two linear portions 39 extending along an extending direction perpendicular to the array direction (portions of a trench which are linear along the extending direction), and an edge portion 41 connecting the two linear portions 39. The extending direction in FIG. 2 is the Y axis direction.

At least part of the edge portion 41 is preferably provided in a curved-line shape in a top view. Connecting end portions of the two linear portions 39 in the Y axis direction by the edge portion 41 can reduce electric field strengths at the end portions of the linear portions 39.

In the transistor portion 70, the dummy trench portion 30 is provided between two adjacent linear portions 39 of the gate trench portion 40. Between the two adjacent linear portions 39, one dummy trench portion 30 may be provided or a plurality of dummy trench portions 30 may be provided. The dummy trench portion 30 may have a linear shape extending in the extending direction, or may have linear portions 29 and an edge portion 31 similarly to the gate trench portion 40. The semiconductor device 100 shown in FIG. 2 includes both the dummy trench portions 30 with a linear shape each of which does not have the edge portion 31, and the dummy trench portions 30 each of which has the edge portion 31.

A diffusion depth of the well region 11 may be deeper than depths of the gate trench portion 40 and the dummy trench portion 30. The end portions in the Y axis direction of the gate trench portion 40 and the dummy trench portion 30 are provided in the well region 11 in a top view. In other words, a bottom portion in a depth direction of each of the trench portions is covered with the well region 11 at an end portion in the Y axis direction of each of the trench portions. With this configuration, an electric field strength at the bottom portion of each of the trench portions can be reduced.

A mesa portion is provided between respective trench portions in the array direction. The mesa portion refers to a region sandwiched between the trench portions in the semiconductor substrate 10. As an example, an upper end of the mesa portion is the upper surface of the semiconductor substrate 10. A depth position of a lower end of the mesa portion is the same as a depth position of a lower end of the trench portion. The mesa portion in this example is provided extending in the extending direction (the Y axis direction) along the trench, at the upper surface of the semiconductor substrate 10. In this example, mesa portions 60 are provided in the transistor portion 70, and mesa portions 61 are provided in the diode portion 80. In a case of simply mentioning “mesa portion” in the present specification, the portion refers to each of a mesa portion 60 and a mesa portion 61.

Each of the mesa portions is provided with base regions 14. In the mesa portion, a region arranged closest to the active-side gate runner 131 among the base regions 14 exposed on the upper surface of the semiconductor substrate 10 is defined as a base region 14-e. While FIG. 2 shows a base region 14-e arranged at one end portion of each of the mesa portions in the extending direction, a base region 14-e is arranged also at another end portion of each of the mesa portions. Each of the mesa portions may be provided with at least one of an emitter region 12 of a first conductivity type or a contact region 15 of the second conductivity type in a region sandwiched between base regions 14-e in a top view. The emitter region 12 in this example is of the N+ type, and the contact region 15 is of the P+ type. The emitter region 12 and the contact region 15 may be provided between the base region 14 and the upper surface of the semiconductor substrate 10 in the depth direction.

The mesa portion 60 of the transistor portion 70 has the emitter regions 12 exposed on the upper surface of the semiconductor substrate 10. The emitter regions 12 are provided in contact with the gate trench portion 40. The mesa portion 60 in contact with the gate trench portion 40 may be provided with the contact regions 15 exposed on the upper surface of the semiconductor substrate 10.

Each of the contact regions 15 and the emitter regions 12 in the mesa portion 60 is provided from one trench portion to another trench portion in the X axis direction. As an example, the contact regions 15 and the emitter regions 12 in the mesa portion 60 are alternately arranged along the extending direction of the trench portion (the Y axis direction).

In another example, the contact regions 15 and the emitter regions 12 of the mesa portion 60 may be provided in a striped pattern along the extending direction of the trench portion (the Y axis direction). For example, the emitter regions 12 are provided in regions in contact with the trench portion, and the contact regions 15 are provided in regions sandwiched between the emitter regions 12.

The mesa portion 61 of the diode portion 80 is not provided with the emitter region 12. The base regions 14 and the contact regions 15 may be provided at an upper surface of the mesa portion 61. In the region sandwiched between the base regions 14-e at the upper surface of the mesa portion 61, the contact region 15 may be provided in contact with each of the base regions 14-e. The base region 14 may be provided in a region sandwiched between the contact regions 15 at the upper surface of the mesa portion 61. The base region 14 may be arranged throughout the region sandwiched between the contact regions 15.

A contact hole 54 is provided above each of the mesa portions. The contact hole 54 is arranged in the region sandwiched between the base regions 14-e. The contact hole 54 in this example is provided above each of the contact regions 15, the base region 14, and the emitter regions 12. The contact hole 54 is not provided in regions corresponding to the base region 14-e and the well region 11. The contact hole 54 may be arranged at a center of the mesa portion 60 in the array direction (the X axis direction).

In the diode portion 80, a cathode region 82 of the N+ type is provided in a region in direct contact with the lower surface of the semiconductor substrate 10. At the lower surface of the semiconductor substrate 10, a collector region 22 of the P+ type may be provided in a region where the cathode region 82 is not provided. The cathode region 82 and the collector region 22 are provided between a lower surface 23 of the semiconductor substrate 10 and a buffer region 20. In FIG. 2, a boundary between the cathode region 82 and the collector region 22 is indicated by a dotted line.

The cathode region 82 is arranged away from the well region 11 in the Y axis direction. With this configuration, a distance between a P type region (the well region 11) having a relatively high doping concentration and formed up to a deep position, and the cathode region 82 is ensured, so that a breakdown voltage can be improved. An end portion in the Y axis direction of the cathode region 82 in this example is arranged farther away from the well region 11 than an end portion in the Y axis direction of the contact hole 54. In another example, the end portion in the Y axis direction of the cathode region 82 may be arranged between the well region 11 and the contact hole 54.

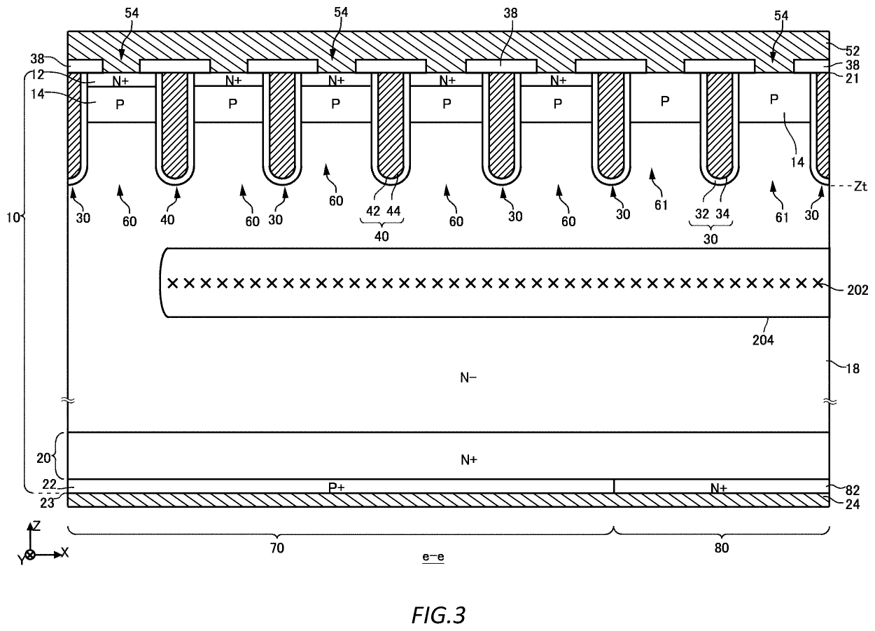

FIG. 3 illustrates an example of a cross section e-e in FIG. 2. The cross section e-e is an XZ plane passing through emitter regions 12 and a cathode region 82. A semiconductor device 100 in this example has a semiconductor substrate 10, an interlayer dielectric film 38, an emitter electrode 52, and a collector electrode 24 in the cross section.

The interlayer dielectric film 38 is provided on an upper surface of the semiconductor substrate 10. The interlayer dielectric film 38 is a film including at least one of a dielectric film such as silicate glass to which an impurity such as boron or phosphorous is added, a thermal oxide film, or another dielectric film. The interlayer dielectric film 38 is provided with the contact holes 54 described in FIG. 2.

The emitter electrode 52 is provided above the interlayer dielectric film 38. The emitter electrode 52 is in contact with an upper surface 21 of the semiconductor substrate 10 through the contact holes 54 of the interlayer dielectric film 38. The collector electrode 24 is provided on a lower surface 23 of the semiconductor substrate 10. The emitter electrode 52 and the collector electrode 24 are formed of a metal material such as aluminum. In the present specification, a direction in which the emitter electrode 52 is connected to the collector electrode 24 (the Z axis direction) is referred to as a depth direction.

The semiconductor substrate 10 has a drift region 18 of the N type or the N− type. The drift region 18 is provided in each of a transistor portion 70 and a diode portion 80.

In a mesa portion 60 of the transistor portion 70, an emitter region 12 of the N+ type and a base region 14 of the P− type are provided in order starting from an upper surface 21 side of the semiconductor substrate 10. The drift region 18 is provided below the base region 14. The mesa portion 60 may be provided with an accumulation region of the N+ type. The accumulation region is arranged between the base region 14 and the drift region 18. The accumulation region is a region of the N+ type having a higher doping concentration than the drift region 18. Providing the accumulation region with a high concentration between the drift region 18 and the base region 14 can increase a carrier injection enhancement effect (IE effect) and reduce an ON-voltage. The accumulation region may be provided to cover the entire lower surface of the base region 14 in each mesa portion 60. The accumulation region may be provided also in each mesa portion 61 of the diode portion 80.

The emitter region 12 is exposed on the upper surface 21 of the semiconductor substrate 10, and is provided in contact with a gate trench portion 40. The emitter region 12 may be in contact with trench portions on both sides of the mesa portion 60. The emitter region 12 has a higher doping concentration than the drift region 18.

The base region 14 is provided below the emitter region 12. The base region 14 in this example is provided in contact with the emitter region 12. The base region 14 may be in contact with the trench portions on both sides of the mesa portion 60.

The mesa portion 61 of the diode portion 80 is provided with a base region 14 of the P− type in contact with the upper surface 21 of the semiconductor substrate 10. The drift region 18 is provided below the base region 14. The base region 14 of the diode portion 80 may be referred to as an anode region 14.

In each of the transistor portion 70 and the diode portion 80, a buffer region 20 of the N+ type may be provided below the drift region 18. A doping concentration in the buffer region 20 is higher than a doping concentration in the drift region 18. The buffer region 20 may have a concentration peak with a higher doping concentration than in the drift region 18. A doping concentration at the concentration peak refers to a doping concentration at a local maximum of the concentration peak. In addition, as the doping concentration in the drift region 18, an average doping concentration value in a region where a doping concentration distribution is substantially flat may be used.

The buffer region 20 may have two or more concentration peaks in the depth direction of the semiconductor substrate 10 (the Z axis direction). The concentration peaks of the buffer region 20 may be provided at the same depth position as that of, for example, a chemical concentration peak of hydrogen (a proton) or phosphorous. The buffer region 20 may function as a field stopper layer which prevents a depletion layer expanding from lower ends of base regions 14 from reaching a collector region 22 of the P+ type and the cathode region 82 of the N+ type.

In the transistor portion 70, the collector region 22 of the P+ type is provided below the buffer region 20. An acceptor concentration in the collector region 22 is higher than an acceptor concentration in the base region 14. The collector region 22 may include an acceptor which is the same as or different from that of the base region 14. The acceptor of the collector region 22 is, for example, boron.

In the diode portion 80, the cathode region 82 of the N+ type is provided below the buffer region 20. A donor concentration in the cathode region 82 is higher than a donor concentration in the drift region 18. A donor of the cathode region 82 is, for example, hydrogen or phosphorous. It should be noted that an element serving as a donor and an acceptor in each region is not limited to the example described above. The collector region 22 and the cathode region 82 are exposed on the lower surface 23 of the semiconductor substrate 10, and are connected to the collector electrode 24. The collector electrode 24 may be in contact with the entire lower surface 23 of the semiconductor substrate 10. The emitter electrode 52 and the collector electrode 24 are formed of a metal material such as aluminum.

One or more gate trench portions 40 and one or more dummy trench portions 30 are provided on the upper surface 21 side of the semiconductor substrate 10. Each of the trench portions is provided from the upper surface 21 of the semiconductor substrate 10 through the base region 14 to below the base region 14. In a region where at least any of the emitter region 12, a contact region 15, or the accumulation region is provided, each of the trench portions also penetrates a doping region described above. The configuration of the trench portions penetrating the doping region is not limited to the one manufactured in the order of forming the doping region and then forming the trench portions. The configuration of the trench portions penetrating the doping region also includes a configuration of forming the trench portions and then forming the doping region between the trench portions.

As described above, the transistor portion 70 is provided with gate trench portions 40 and dummy trench portions 30. The diode portion 80 is provided with dummy trench portions 30, and is not provided with a gate trench portion 40. A boundary in the X axis direction between the diode portion 80 and the transistor portion 70 in this example is a boundary between the cathode region 82 and the collector region 22.

The gate trench portion 40 has a gate trench provided at the upper surface 21 of the semiconductor substrate 10, a gate dielectric film 42, and a gate conductive portion 44. The gate dielectric film 42 is provided covering an inner wall of the gate trench. The gate dielectric film 42 may be formed by oxidizing or nitriding a semiconductor on the inner wall of the gate trench. The gate conductive portion 44 is provided farther inward than the gate dielectric film 42 in the gate trench. In other words, the gate dielectric film 42 insulates the gate conductive portion 44 from the semiconductor substrate 10. The gate conductive portion 44 is formed of a conductive material such as polysilicon.

The gate conductive portion 44 may be provided to be longer than the base region 14 in the depth direction. The gate trench portions 40 in the cross section are covered with the interlayer dielectric film 38 on the upper surface 21 of the semiconductor substrate 10. The gate conductive portion 44 is electrically connected to a gate runner. When a predetermined gate voltage is applied to the gate conductive portion 44, a channel is formed by an electron inversion layer in a surface layer of the base region 14 at a boundary in contact with the gate trench portion 40.

The dummy trench portion 30 may have the same structure as that of the gate trench portion 40 in the cross section. The dummy trench portion 30 has a dummy trench provided at the upper surface 21 of the semiconductor substrate 10, a dummy dielectric film 32, and a dummy conductive portion 34. The dummy conductive portion 34 is electrically connected to the emitter electrode 52. The dummy dielectric film 32 is provided covering an inner wall of the dummy trench. The dummy conductive portion 34 is provided in the dummy trench, and is provided farther inward than the dummy dielectric film 32. The dummy dielectric film 32 insulates the dummy conductive portion 34 from the semiconductor substrate 10. The dummy conductive portion 34 may be formed of the same material as that of the gate conductive portion 44. For example, the dummy conductive portion 34 is formed of a conductive material such as polysilicon. The dummy conductive portion 34 may have the same length as that of the gate conductive portion 44 in the depth direction.

The gate trench portions 40 and the dummy trench portions 30 in this example are covered with the interlayer dielectric film 38 on the upper surface 21 of the semiconductor substrate 10. It should be noted that bottom portions of the dummy trench portion 30 and the gate trench portion 40 may be formed in a curved-surface shape (a curved-line shape in the cross section) convexly downward. In the present specification, a depth position of a lower end of the gate trench portion 40 is defined as Zt.

The semiconductor device 100 in this example includes a first lifetime region 204 which adjusts a carrier lifetime. The first lifetime region 204 in this example is a region where a lifetime of charge carriers is locally short. The charge carriers are electrons or holes. The charge carriers may be simply referred to as carriers. The first lifetime region 204 may be a region where the carrier lifetime has a local minimum value in the depth direction of the semiconductor substrate 10.

The first lifetime region 204 is arranged on the upper surface 21 side of the semiconductor substrate 10. The first lifetime region 204 is provided in the diode portion 80. The first lifetime region 204 may be provided also in part of the transistor portion 70. In the example shown in FIG. 3, the first lifetime region 204 is provided in a region that is in the transistor portion 70 and that is in contact with the diode portion 80.

Implanting charged particles such as helium into the semiconductor substrate 10 forms lattice defects 202 in the vicinity of an implantation position. In FIG. 3, the lattice defects 202 at the implantation position of the charged particles are schematically indicated by X marks. In a region where many lattice defects 202 remain, the carriers are captured by the lattice defects 202, and thus the lifetime of the carriers is shortened. Adjusting the lifetime of the carriers can adjust characteristics such as a turn-off time and a reverse recovery loss in the diode portion 80. Implanting the charged particles such as helium into the semiconductor substrate 10 forms the lattice defects 210 such as vacancies in the vicinity of an implantation position. The lattice defects 202 generate recombination centers. The lattice defects 202 may be mainly composed of vacancies such as monatomic vacancies (V) or diatomic vacancies (VV), may be dislocations, may be interstitial atoms, or may be transition metals or the like. For example, atoms adjacent to the vacancies have dangling bonds. In a broad sense, the lattice defects 202 may also include donors and acceptors, but in the present specification, the lattice defects 202 mainly composed of vacancies may be referred to as vacancy-type lattice defects, vacancy-type defects, or simply lattice defects. In the present specification, the lattice defects 202 may be simply referred to as recombination centers or lifetime killers as recombination centers contributing to recombination of carriers. The lifetime killers may be formed by implanting helium ions into the semiconductor substrate 10. In this case, a helium chemical concentration may be used as a density of the lattice defects 202. In this example, a helium chemical concentration may be used as a density of the lattice defects 202.

On the other hand, providing the first lifetime region 204 in the diode portion 80 decreases, in the first lifetime region 204, holes implanted from the anode region 14 and electrons implanted from the cathode region 82 during forward conduction of the diode portion 80. This makes it difficult for a potential difference at a PN junction between the anode region 14 and the drift region 18 to become smaller than a built-in potential, and snapback of a forward voltage may occur in a low current operation region. Especially, providing the first lifetime region 204 throughout the diode portion 80 in the X axis direction makes it difficult for a hole density and an electron density in a region of the diode portion 80 on the upper surface 21 side to increase, and the snapback easily occurs.

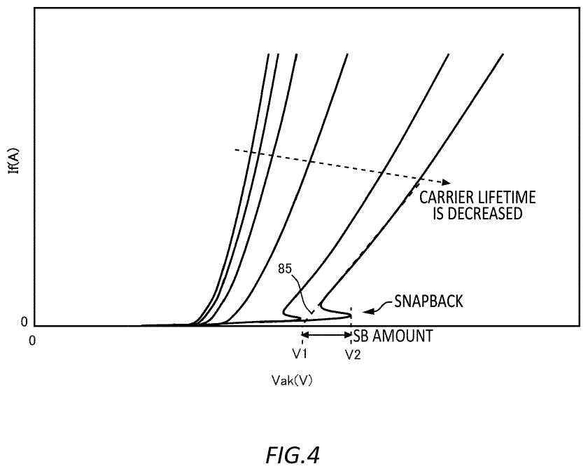

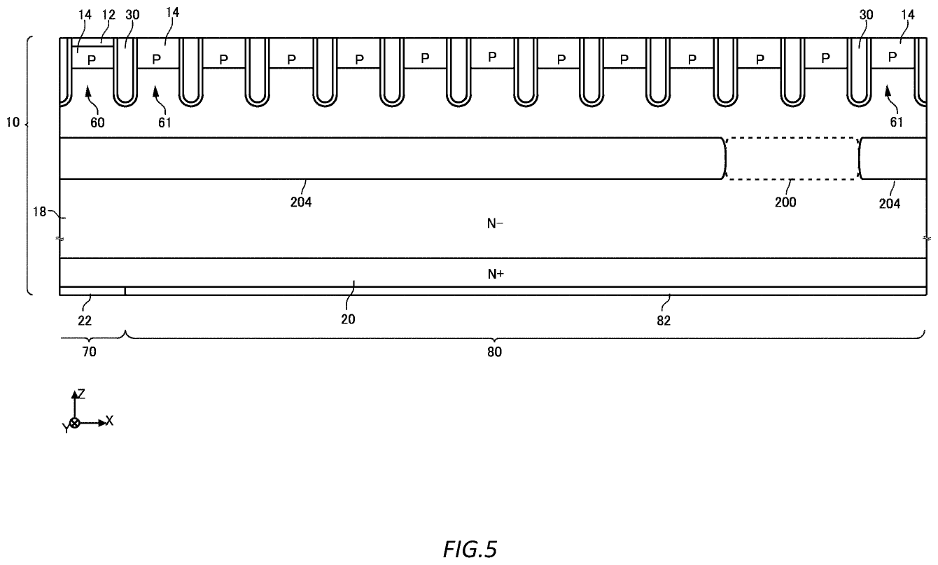

FIG. 4 illustrates examples of V-I characteristics during forward conduction of a diode portion 80 according to a comparative example. In the diode portion 80 in this example, a first lifetime region 204 is provided throughout in the X axis direction. FIG. 4 shows a relationship between a forward current If of the diode portion 80 and an anode-cathode voltage Vak. In addition, FIG. 4 shows V-I characteristics in a plurality of examples in which carrier lifetimes in the first lifetime region 204 are different. A carrier lifetime in the first lifetime region 204 can be adjusted by adjusting a dose amount of charged particles such as helium to be implanted into a semiconductor substrate 10. A greater dose amount of the charged particles such as helium increases a density of lattice defects formed in the semiconductor substrate 10, and decreases the carrier lifetime.

When the first lifetime region 204 is provided throughout the diode portion 80, decreasing the carrier lifetime in the first lifetime region 204 may cause snapback in a V-I characteristic as shown in FIG. 4. As shown in FIG. 4, the snapback is a phenomenon in which an increase in a current is suppressed until the voltage Vak reaches a predetermined value in a low current operation region during the forward conduction and in which the current rapidly increases once the voltage Vak exceeds the predetermined value. In the low current operation region, it is necessary to increase a majority carrier density (an electron density in this example) for a potential difference at a PN junction to exceed a built-in potential. In order to supply the electron density required to exceed the built-in potential, a shorter carrier lifetime requires a higher anode-cathode voltage Vak. When the potential difference at the PN junction exceeds the built-in potential, implantation of minority carriers starts, and a resistance of the diode portion 80 decreases as the forward current increases. As a result, the anode-cathode voltage Vak decreases to cause conductivity modulation, and the snapback occurs in the V-I characteristics.

A V-I waveform in a large current operation region is approximated by a straight line 85. In the present specification, a difference between a voltage V1 at which the current If=0 is established on the straight line 85 and a peak voltage V2 at the snapback (V2−V1) may be referred to as a snapback amount (an SB amount). In a semiconductor device 100, the snapback is suppressed by adjusting an arrangement of the first lifetime region 204 in the diode portion 80.

FIG. 5 illustrates an arrangement example of a first lifetime region 204 and a second lifetime region 200 in a diode portion 80. FIG. 5 shows an XZ cross section passing through part of the diode portion 80 and part of a transistor portion 70. In FIG. 5, illustration of an interlayer dielectric film 38, an emitter electrode 52, a collector electrode 24, and the like which are arranged above and below a semiconductor substrate 10 is omitted. In FIG. 5, illustration of lattice defects 202 is omitted, and hatching for dummy conductive portions 34 and gate conductive portions 44 is omitted.

The diode portion 80 in this example has first lifetime regions 204 and a second lifetime region 200 in a region on an upper surface 21 side of the semiconductor substrate 10. The first lifetime regions 204 are arranged in a drift region 18 on a lower surface 23 side of the semiconductor substrate 10 relative to a base region 14. The first lifetime regions 204 may be arranged below lower ends of dummy trench portions 30. The diode portion 80 may be provided with a plurality of first lifetime regions 204 which are arranged away from each other in the X axis direction. A width of one first lifetime region 204 in the X axis direction may be greater than a width of one mesa portion sandwiched between two trench portions.

The second lifetime region 200 is arranged to be sandwiched between the first lifetime regions 204 in a first direction (the X axis direction in this example) parallel to an upper surface 21 of the semiconductor substrate 10. The first lifetime regions 204 and the second lifetime region 200 are provided at the same position in a depth direction of the semiconductor substrate 10 (the Z axis direction).

The second lifetime region 200 is a region having a longer carrier lifetime than a first lifetime region 204. A carrier lifetime in the second lifetime region 200 in this example may be the same as a carrier lifetime in the drift region 18. In other words, the second lifetime region 200 may be the drift region 18 which has remained without the first lifetime regions 204 being formed. In another example, the carrier lifetime in the second lifetime region 200 may be shorter than the carrier lifetime in in the drift region 18.

A lattice defect density in the second lifetime region 200 is lower than a lattice defect density in the first lifetime region 204. The lattice defect density in the second lifetime region 200 may be the same as a lattice defect density in the drift region 18, or may be higher than a lattice defect density in the drift region 18. A concentration of impurities such as helium in the second lifetime region 200 may be lower than a concentration of impurities such as helium in the first lifetime region 204. The concentration of impurities such as helium in the second lifetime region 200 may be the same as a concentration of impurities in the drift region 18, or may be higher than a concentration of impurities in the drift region 18. The impurities in the concentration of impurities in this example may be impurities serving as lattice defects which decrease a carrier lifetime. For example, the impurities may be atoms other than atoms of the semiconductor substrate 10, or may be interstitial atoms of atoms of the semiconductor substrate 10. In addition, the impurities may be dopants of an n type or a p type, may be impurities which do not contribute to a conductivity type (for example, helium, argon), or may be metal atoms (platinum, gold, and the like). Alternatively, the lattice defects which decrease the carrier lifetime may be vacancies or interstitial atoms which do not contain impurities.

The carrier lifetime in the second lifetime region 200 is longer than a carrier lifetime in the first lifetime region 204, and thus electrons or holes easily pass therethrough. As in this example, providing the second lifetime region 200 in the diode portion 80 allows electrons implanted from a cathode region 82 and holes implanted from the anode region 14 during forward conduction of the diode portion 80 to pass through the second lifetime region 200. The electrons which have passed through the second lifetime region 200 diffuse in an XY plane, and expand above the first lifetime regions 204. The holes which have passed through the second lifetime region 200 diffuse in the XY plane, and expand below the first lifetime regions 204. This can improve an electron density and a hole density in regions on the upper surface 21 side and the lower surface 23 side relative to the first lifetime region 204, especially during low current operation during the forward conduction of the diode portion 80. As a result, it is possible to cause conductivity modulation without increasing an anode-cathode voltage Vak and to suppress snapback. In this example, one second lifetime region 200 is provided in one diode portion 80. The second lifetime region 200 may be arranged at a center of the diode portion 80 in the X axis direction.

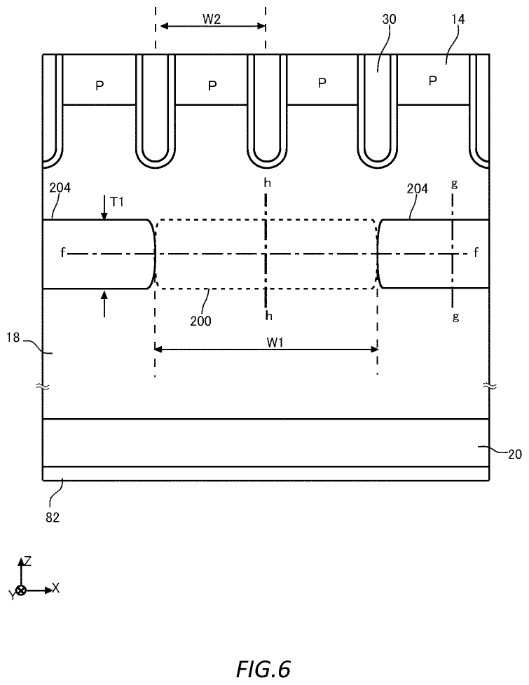

FIG. 6 illustrates an enlarged cross sectional view in the vicinity of a second lifetime region 200. A width of the second lifetime region 200 in a first direction (the X axis direction in this example) is defined as W1. A thickness of a first lifetime region 204 in a second direction (the Z axis direction in this example) perpendicular to an upper surface 21 of a semiconductor substrate 10 is defined as T1. The width W1 of the second lifetime region 200 is 0.2 times or more the thickness of the first lifetime region 204. If the width W1 of the second lifetime region 200 is too small, electrons or holes are easily captured by lattice defects 202 in first lifetime regions 204 on both sides of the second lifetime region 200 when the electrons or the holes pass through the second lifetime region 200. The lattice defects 202 capturing the electrons or the holes may have trap levels. In addition, when the thickness T1 of the first lifetime region 204 increases, the electrons or the holes passing through the second lifetime region 200 are easily captured by the lattice defects 202 in the first lifetime regions 204. In contrast, setting the width W1 of one second lifetime region 200 to 0.2 times or more the thickness of the first lifetime region 204 can ensure amounts of the electrons and the holes passing through the second lifetime region 200. The width W1 may be 0.25 times or more, may be 0.3 times or more, may be 0.4 times or more, may be 0.5 times or more, may be one time or more, or may be twice or more, the thickness T1.

Note that, however, when the second lifetime region 200 is too large, a reverse recovery time of a diode portion 80 will be longer, and a reverse recovery charge and a reverse recovery loss will also increase. In the diode portion 80, a total width of the second lifetime region 200 in the X axis direction is preferably smaller than a total width of the first lifetime region 204. The total width of the second lifetime region 200 in the X axis direction in the diode portion 80 may be smaller than or equal to 10%, or may be smaller than or equal to 5%, of a width of the diode portion 80 in the X axis direction.

One diode portion 80 may have one second lifetime region 200, or may have a plurality of second lifetime regions 200 which are arranged away from each other in the X axis direction. The width W1 of each of the second lifetime regions 200 may be 7 μm or greater. Increasing the width W1 of the second lifetime region 200 can suppress the electrons or the holes from being captured by the lattice defects 202 in the first lifetime regions 204 on both sides of the second lifetime region 200 when the electrons or the holes pass through the second lifetime region 200. The width W1 may be 8 μm or greater, or may be 9 μm or greater. The width W1 may be 12 μm or smaller. When the width W1 is too great, a turn-off time of the diode portion 80 will increase, and the reverse recovery loss will also increase. The width W1 may be 11 μm or smaller, or may be 10 μm or smaller.

An interval between trench portions (dummy trench portions 30 in this example) in the X axis direction is defined as W2. The interval between the trench portions may be an interval between central positions of the trench portions in the X axis direction. The width W1 of the second lifetime region 200 may be greater than the interval W2 between the trench portions. In other words, the width W1 of the second lifetime region 200 may be greater than a mesa width of a mesa portion sandwiched between two trench portions which are adjacent to each other in the X axis direction. The width W1 may be 1.2 times or more, may be 1.5 times or more, or may be twice or more, the interval W2. The width W1 may be ten times or less, may be five times or less, or may be three times or less, the interval W2.

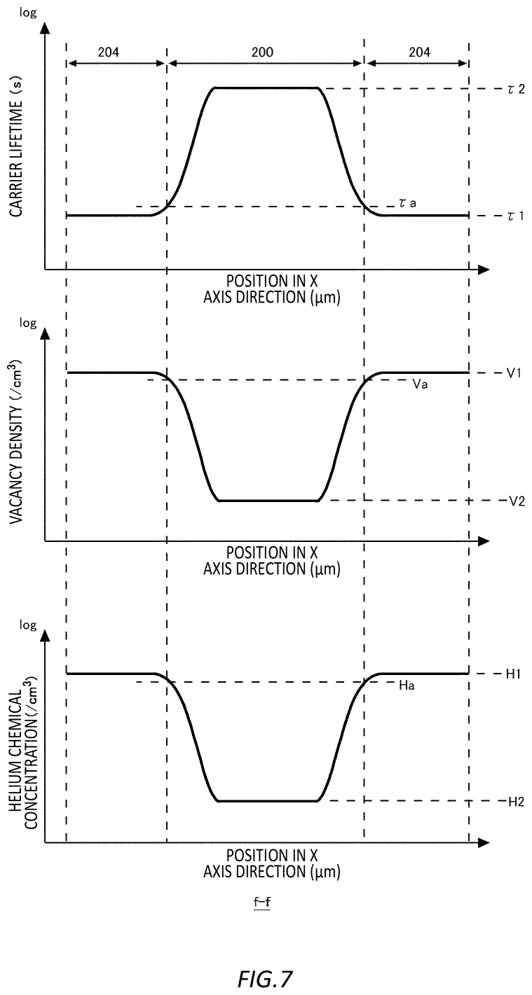

FIG. 7 illustrates distribution examples of carrier lifetimes, vacancy densities, and helium chemical concentrations on a line f-f in FIG. 6. The line f-f is a straight line being parallel to the X axis direction and passing through two first lifetime regions 204 and one second lifetime region 200. A carrier lifetime in a first lifetime region 204 is defined as τ1, and a carrier lifetime in the second lifetime region 200 is defined as τ2. A minimum carrier lifetime value in the first lifetime region 204 may be used as the carrier lifetime τ1. A maximum carrier lifetime value in the second lifetime region 200 may be used as the carrier lifetime τ2. The carrier lifetime τ2 may be the same as or shorter than a carrier lifetime in a drift region 18. A value at a center of the drift region 18 in a depth direction may be used, or an average value may be used, as the carrier lifetime in the drift region 18.

Positions at which the carrier lifetime is τa are defined as boundary positions between the first lifetime regions 204 and the second lifetime region 200. τa is a value greater than or equal to τ1 and smaller than or equal to τ2. τa may be the same as either τ1 or τ2, or may be a value obtained by multiplying either τ1 or τ2 by a predetermined coefficient. τa may be a value slightly greater than τ1, may be an average value of τ1 and τ2, or may be another value. Positions at which the carrier lifetime is greater than τ1 may be defined as the boundary positions between the first lifetime regions 204 and the second lifetime region 200. The carrier lifetime τ2 in the second lifetime region 200 may be ten times or more, may be one hundred times or more, or may be one thousand times or more, the carrier lifetime τ1 in the first lifetime region 204. As an example, the carrier lifetime τ1 is 100 ns or smaller, and the carrier lifetime τ2 is 1 μs or greater. τ1 may be 10 ns or smaller, and τ2 may be 10 μs or greater.

A vacancy density in the first lifetime region 204 is defined as V1, and a vacancy density in the second lifetime region 200 is defined as V2. A maximum vacancy density value in the first lifetime region 204 may be used as the vacancy density V1. A minimum vacancy density value in the second lifetime region 200 may be used as the vacancy density V2. The vacancy density V2 may be the same as or greater than a vacancy density in the drift region 18. A value at the center of the drift region 18 in the depth direction may be used, or an average value may be used, as the vacancy density in the drift region 18.

Positions at which the vacancy density is Va may be defined as the boundary positions between the first lifetime regions 204 and the second lifetime region 200. Va is a value greater than or equal to V2 and smaller than or equal to V1. Va may be the same as either V1 or V2, or may be a value obtained by multiplying either V1 or V2 by a predetermined coefficient. Va may be a value slightly smaller than V1, may be an average value of V1 and V2, or may be another value. Positions at which the vacancy density is smaller than V1 may be defined as the boundary positions between the first lifetime regions 204 and the second lifetime region 200.

A helium chemical concentration in the first lifetime region 204 is defined as H1, and a helium chemical concentration in the second lifetime region 200 is defined as H2. A maximum helium chemical concentration value in the first lifetime region 204 may be used as the helium chemical concentration H1. A minimum helium chemical concentration value in the second lifetime region 200 may be used as the helium chemical concentration H2. The helium chemical concentration H2 may be the same as or greater than a helium chemical concentration in the drift region 18. A value at the center of the drift region 18 in the depth direction may be used, or an average value may be used, as the helium chemical concentration in the drift region 18.

Positions at which the helium chemical concentration is Ha may be defined as the boundary positions between the first lifetime regions 204 and the second lifetime region 200. Ha is a value greater than or equal to H2 and smaller than or equal to H1. Ha may be the same as either H1 or H2, or may be a value obtained by multiplying either H1 or H2 by a predetermined coefficient. Ha may be a value slightly smaller than H1, may be an average value of H1 and H2, or may be another value. Positions at which the helium chemical concentration is smaller than H1 may be defined as the boundary positions between the first lifetime regions 204 and the second lifetime region 200. When lattice defects are formed by implanting charged particles other than helium, the boundary positions between the first lifetime regions 204 and the second lifetime region 200 may be determined based on a chemical concentration of the charged particles.

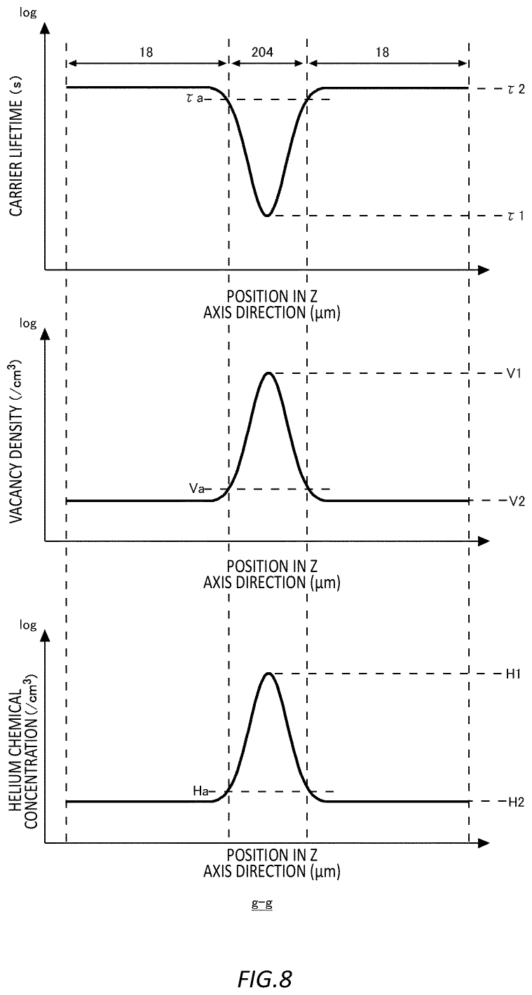

FIG. 8 illustrates distribution examples of carrier lifetimes, vacancy densities, and helium chemical concentrations on a line g-g in FIG. 6. The line g-g is a straight line crossing a first lifetime region 204 in the Z axis direction. The first lifetime region 204 in this example is sandwiched between drift regions 18 in the Z axis direction. In this example, a carrier lifetime, a vacancy density, and a helium chemical concentration in a drift region 18 are respectively τ2, V2, and H2.

Positions at which the carrier lifetime is τa may be defined as boundary positions between the first lifetime region 204 and the drift regions 18. The carrier lifetime τa is similar to the one in the example described in FIG. 7. Positions at which the carrier lifetime is smaller than τ2 may be defined as the boundary positions between the first lifetime region 204 and the drift regions 18. Positions at which the vacancy density is Va may be defined as the boundary positions between the first lifetime region 204 and the drift regions 18. The vacancy density Va is similar to the one in the example described in FIG. 7. Positions at which the vacancy density is greater than V2 may be defined as the boundary positions between the first lifetime region 204 and the drift regions 18. Positions at which the helium chemical concentration is Ha may be defined as the boundary positions between the first lifetime region 204 and the drift regions 18. The helium chemical concentration Ha is similar to the one in the example described in FIG. 7. Positions at which the helium chemical concentration is greater than H2 may be defined as boundary positions between the first lifetime regions 204 and the drift region 18. A carrier lifetime distribution in the first lifetime region 204 may be a distribution in which the carrier lifetime decreases from τ2 as in a Gaussian function. A vacancy density distribution in the first lifetime region 204 may be a distribution in which the vacancy density increases from V2 as in the Gaussian function. A helium chemical concentration distribution in the first lifetime region 204 may be a distribution in which the helium chemical concentration increases from H2 as in the Gaussian function.

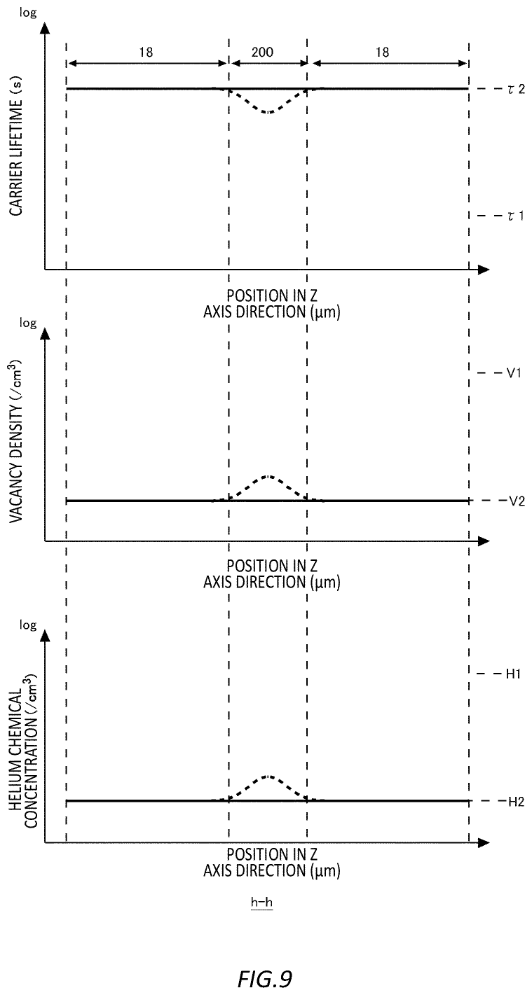

FIG. 9 illustrates distribution examples of carrier lifetimes, vacancy densities, and helium chemical concentrations on a line h-h in FIG. 6. The line h-h is a straight line crossing a second lifetime region 200 in the Z axis direction. The second lifetime region 200 in this example is sandwiched between drift regions 18 in the Z axis direction.

In this example, a carrier lifetime, a vacancy density, and a helium chemical concentration in each of the second lifetime region 200 and a drift region 18 are respectively τ2, V2, and H2. In another example, the carrier lifetime in the second lifetime region 200 may be shorter than the carrier lifetime in the drift region 18 as indicated by a broken line in FIG. 9. The vacancy density in the second lifetime region 200 may be higher than the vacancy density in the drift region 18 as indicated by a broken line in FIG. 9. The helium chemical concentration in the second lifetime region 200 204 may be higher than the helium chemical concentration in the drift region 18 as indicated by a broken line in FIG. 9. A carrier lifetime distribution in the second lifetime region 200 may be a distribution in which the carrier lifetime decreases from τ2 as in a Gaussian function. A vacancy density distribution in the second lifetime region 200 may be a distribution in which the vacancy density increases from V2 as in the Gaussian function. A helium chemical concentration distribution in the second lifetime region 200 may be a distribution in which the helium chemical concentration increases from H2 as in the Gaussian function.

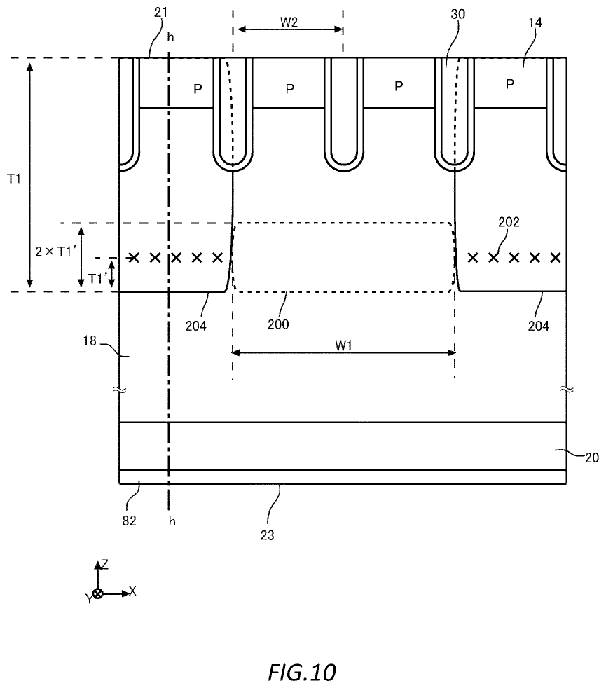

FIG. 10 illustrates another example of an enlarged cross sectional view in the vicinity of a second lifetime region 200. In this example, first lifetime regions 204 are formed by implanting hydrogen ions into a semiconductor substrate 10. Implanting the hydrogen ions forms lattice defects 202 in a passed-through region through which the hydrogen ions have passed. The hydrogen ions may be implanted from an upper surface 21 of the semiconductor substrate 10. The first lifetime regions 204 may be formed up to the upper surface 21 of the semiconductor substrate 10. Except for the first lifetime regions 204, this example has a structure similar to the one in any aspect described in the present specification.

When the first lifetime regions 204 are formed up to the upper surface 21 of the semiconductor substrate 10, a thickness T1 is a distance from a lower end of a first lifetime region 204 to the upper surface 21. As described in the present specification, a width W1 of the second lifetime region 200 may be determined according to the thickness T1. A distance in a depth direction from a depth position of a density peak of the lattice defects 202 to the lower end of the first lifetime region 204 is defined as T1′. 2×T1′ may be used as the thickness T1 of the first lifetime region 204.

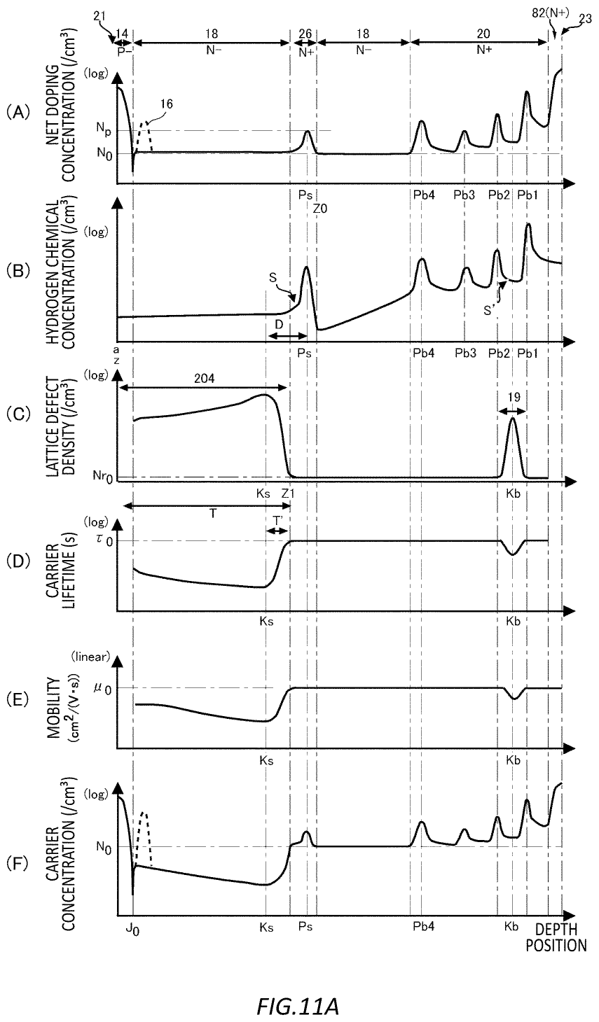

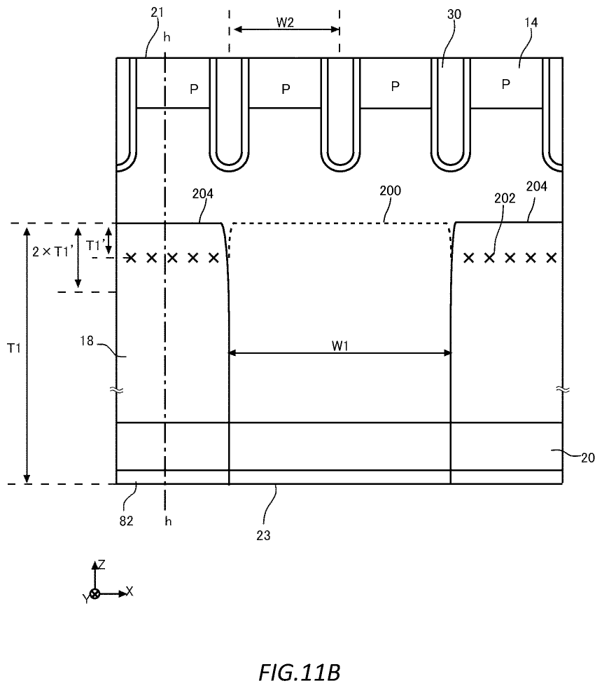

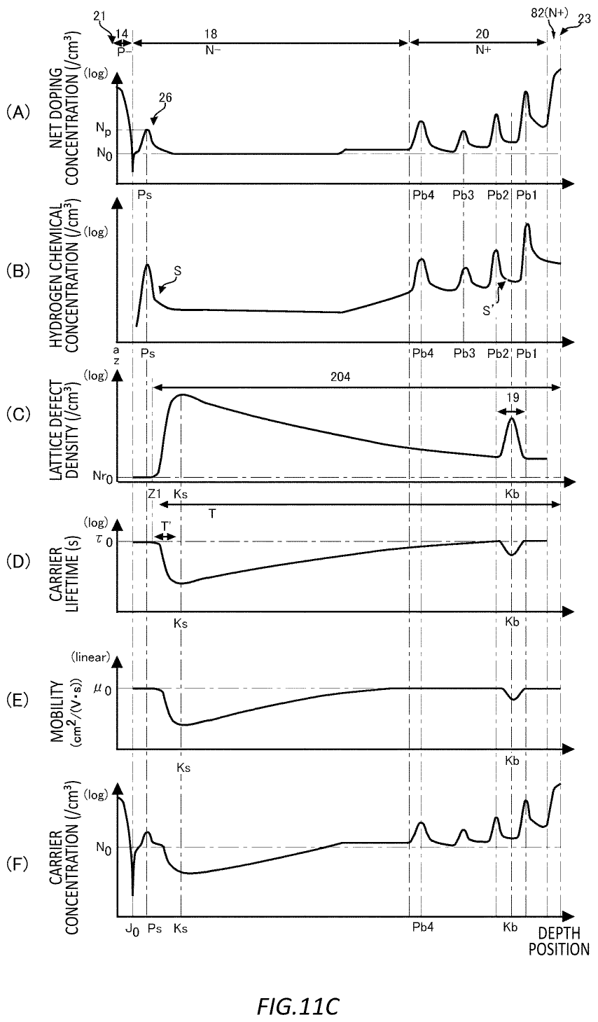

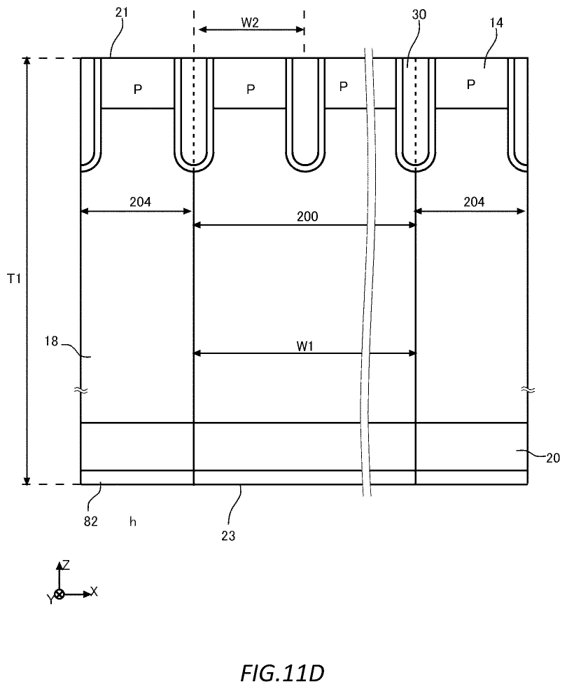

FIG. 11A shows each of a distribution diagram of a net doping concentration (A), a distribution diagram of a hydrogen chemical concentration (B), a distribution diagram of a lattice defect density (C), a distribution diagram of a carrier lifetime (D), a distribution diagram of carrier mobility (E), and a distribution diagram of a carrier concentration (F) along a line h-h in a semiconductor device 100 according to the embodiment example shown in FIG. 10. The horizontal axis in each of the distribution diagrams represents a position in a depth direction. In this example, hydrogen ions are implanted at a depth position Ps from an upper surface 21 to form a first lifetime region 204. In addition, a buffer region 20 has a plurality of doping concentration peaks. In FIG. 11A, it has a doping concentration peak at each of depth positions Pb1 to Pb4 in order starting from a depth position closer to a lower surface 23. In addition, a depth position Kb is provided with a lower-surface side lifetime region 19 which is formed by radiating charged particles such as helium.

The distribution diagram (A) shows a net doping concentration distribution of electrically activated donors and acceptors. In this example, a peak of a concentration Nₚ due to hydrogen donors is provided at the position Ps. In FIG. 11A, a region provided with the peak is defined as a high concentration region 26. The doping concentration in part of a region on a lower surface 23 side relative to the position Ps is a doping concentration N₀. The doping concentration N₀ may be a bulk donor concentration. Bulk donors of a semiconductor substrate 10 may be phosphorous, may be antimony, or may be arsenic, and further, there may be bulk acceptors (boron, aluminum, indium, or the like) to the extent that the bulk donor concentration is not exceeded.

In the distribution diagram (A), a region of the N type having a doping concentration higher than the doping concentration in drift regions 18 is defined as the N+ type. The doping concentration in at least part of a drift region 18 between the position Ps and the position Pb4 may be lower than the doping concentration in a drift region 18 on an upper surface 21 side relative to the position Ps. The hydrogen ions implanted from the upper surface 21 of the semiconductor substrate 10 pass through the drift region 18 on the upper surface 21 side. Therefore, the doping concentration in the drift region 18 may be higher than the doping concentration N₀ of the semiconductor substrate 10 due to remaining hydrogen donors. An average doping concentration value in the drift region 18 on the upper surface 21 side may be three times or less the doping concentration N₀ of the semiconductor substrate 10.

The hydrogen ions are implanted at the positions Pb4, Pb3, Pb2, and Pb1 from the lower surface 23 of the semiconductor substrate 10. Therefore, the doping concentration in a region on the lower surface 23 side relative to the position Pb4 may be higher than the doping concentration N₀ of the semiconductor substrate 10 as a whole. That is, the doping concentration (a donor concentration in this example) in the drift region 18 in a region sandwiched in the depth direction between two hydrogen donor peaks (respective hydrogen donor peaks at the position Ps and the position Pb4 in this example) is the lowest. The doping concentration (the donor concentration in this example) in the region sandwiched between these two hydrogen donor peaks is the doping concentration N₀ of the semiconductor substrate 10, and the doping concentration distribution may be substantially flat. The fact that the doping concentration distribution is substantially flat may be for a case where, in a region with a predetermined percentage with respect to a distance between the position Ps and the position Pb4, a concentration difference between maximum and minimum doping concentration values is smaller than or equal to 50% of an average doping concentration value in the region. The predetermined percentage may be any value within a range greater than or equal to 50% and smaller than or equal to 80% with respect to the distance between the position Ps and the position Pb4. Due to the hydrogen donors, the doping concentration in regions on the upper surface 21 side relative to the position Ps and on the lower surface 23 side relative to the position Pb4 may be higher than the doping concentration N₀ of the semiconductor substrate 10. It should be noted that a cathode region 82 in this example is formed by implanting, and diffusing or electrically activating phosphorous.

As indicated by a broken line in FIG. 11A, an accumulation region 16 of the N+ type may be provided between an anode region 14 and the drift region 18. The accumulation region 16 may be continuously provided from one to another of two trench portions which are adjacent to each other in the X axis direction, in each mesa portion.

The distribution diagram (B) shows a chemical concentration of implanted hydrogen (a hydrogen chemical concentration). Each peak of the hydrogen chemical concentration has a tail on a principal surface side from which the hydrogen ions have been implanted. In this example, a peak of the hydrogen chemical concentration at the position Ps has a tail S on the upper surface 21 side. That is, in a hydrogen chemical concentration distribution in this example, the hydrogen chemical concentration monotonically decreases gradually from the first position Ps to the upper surface 21 on the upper surface 21 side. The tail S may be provided over the drift region 18 and the anode region 14.

The hydrogen chemical concentration distribution in this example has tails at which the concentration distribution changes more steeply than at the tail S, on the lower surface 23 side relative to the position Ps. That is, the hydrogen chemical concentration distribution exhibits an asymmetric distribution on the upper surface 21 side and the lower surface 23 side relative to the position Ps.

In addition, a peak of the hydrogen chemical concentration at each of the positions Pb4, Pb3, Pb2, and Pb1 has a tail S′ on the lower surface 23 side. The peak of the hydrogen chemical concentration at each of the positions Pb4, Pb3, Pb2, and Pb1 has a tail at which the concentration distribution changes more steeply than at the tail S′, on the upper surface 21 side. That is, the peak of the hydrogen chemical concentration at each of the positions Pb4, Pb3, Pb2, and Pb1 shows an asymmetric distribution on the upper surface 21 side and the lower surface 23 side relative to the position.

It should be noted that the hydrogen chemical concentration may have a minimum value between a position closest to the lower surface 23 among positions at which the hydrogen ions have been implanted from the upper surface 21 side (the position Ps in this example) and a position closest to the upper surface 21 among positions at which the hydrogen ions have been implanted from the lower surface 23 side (the position Pb4 in this example). A position at which a sum of a distribution of diffusion of hydrogen implanted at the position Ps and a distribution of diffusion of hydrogen implanted at the position Pb4 is minimum is a position at which the hydrogen chemical concentration has the minimum value. Alternatively, the position at which the hydrogen chemical concentration has the minimum value may be in a region sandwiched between two hydrogen donor peaks (the position Ps and the position Pb4 in this example) and having a substantially flat doping concentration distribution in which the doping concentration exhibits the doping concentration N₀ of the semiconductor substrate 10. Alternatively, the position at which the hydrogen chemical concentration has the minimum value may be the upper surface 21.

The distribution diagram (C) shows a lattice defect density after the hydrogen ions are implanted into the semiconductor substrate 10 and then annealing is performed under a predetermined condition. A position at which the net doping concentration in the high concentration region 26 is substantially identical to the doping concentration N₀ of the semiconductor substrate 10 on the lower surface 23 side relative to the position Ps is defined as a position Z0. On the lower surface 23 side relative to the position Z₀, the lattice defect density may have a sufficiently small value Nr₀. The fact that the lattice defect density has the sufficiently small value Nr₀ is that the lattice defect density has a low value to the extent that a lifetime of carriers does not become smaller than τ₀ mentioned below. As an example, assuming that a concentration of vacancies or divacancies is Nr₀, at a temperature of 300K, Nr₀ may be 1×10¹² atoms/cm³ or smaller, may be 1×10¹¹ atoms/cm³ or smaller, or may be 1×10¹⁰ atoms/cm³ or smaller. The lattice defect density may be higher than Nr₀ at a position J₀ of a pn junction between the anode region 14 and the drift region 18 or the accumulation region 16.

In the vicinity of the position Ps and in a passed-through region from the upper surface 21 to the position Ps, lattice defects are formed due to passage of the hydrogen ions. This allows the first lifetime region 204 to be formed. Note that, however, in the vicinity of the position Ps, the lattice defects are terminated by hydrogen, and thus a distribution of the lattice defect density and a distribution of the hydrogen chemical concentration have different shapes. For example, the peak position Ps of the hydrogen chemical concentration does not match a peak position Ks of the lattice defect density. The peak position Ks of the lattice defect density in this example is arranged on the upper surface 21 side of the semiconductor substrate 10 relative to the peak position Ps of the hydrogen chemical concentration. The lattice defect density may monotonically decrease on the upper surface 21 side relative to the position Ks. The lattice defect density may monotonically decrease, on the lower surface 23 side relative to the position Ks, more steeply than on the upper surface 21 side.

In the vicinity of the peak position Ps of the hydrogen chemical concentration, a large amount of hydrogen terminates dangling bonds such as vacancies and divacancies. Therefore, the lattice defect density in the vicinity of the peak position Ps of the hydrogen chemical concentration is much smaller than the lattice defect density at the peak position Ks of the lattice defect density. In the present specification, a width of a distribution showing a concentration greater than 1% of a peak concentration is referred to as a 1% full width or FW1% M. The vicinity of the peak position Ps may refer to a region within a range of the 1% full width centered on the peak position Ps. The peak position Ks of the lattice defect density may be provided at a position shallower than that of the range of the 1% full width centered on the peak position Ps.

Note that, however, a distance D between the peak position Ks of the lattice defect density and the peak position Ps of the hydrogen chemical concentration is determined according to a distance over which hydrogen diffuses in the semiconductor substrate 10 through annealing. The distance D may be 40 μm or smaller, may be 20 μm or smaller, or may be 10 μm or smaller. The distance D may be 1 μm or greater, may be 3 μm or greater, or may be 5 μm or greater. The distance D may be greater than or equal to, or greater than the 1% full width of the hydrogen chemical concentration. The distance D may be greater than or equal to, or greater than the 1% full width of the net doping concentration at the position Ps. In this case, the 1% full width of the net doping concentration is a width of a peak at 0.01 Np. A range of a value of the distance D may be a combination of any lower limit value and any upper limit value described above. A lattice defect density distribution can be observed by measuring a density distribution of vacancies and divacancies by a positron annihilation method, as an example.

A depth position at which the lattice defect density first becomes identical to Nr₀ from the upper surface 21 toward the lower surface 23 is defined as Z1. The first lifetime region 204 may be provided from the upper surface 21 to the position Z1. As described in FIG. 10, a distance from the upper surface 21 to the position Z1 may be defined as a thickness T1. In another example, a distance equivalent to twice a distance T′ from the position Ks to the position Z1 may be used as the thickness T1. The first lifetime region 204 in this example contains hydrogen donors.

A peak of the lattice defect density (the lower-surface side lifetime region 19) may be arranged between the lower surface 23 and the position Pb4. In this example, the peak of the lattice defect density (the lower-surface side lifetime region 19) is arranged at the position Kb between the position Pb2 and the position Pb1. The peak of the lattice defect density at the position Kb mainly includes lattice defects formed when helium ions have been implanted between the position Pb2 and the position Pb1 from the lower surface 23. In this example, no peak of the lattice defect density is provided at a position other than the position Kb, on the lower surface 23 side relative to the position Pb4.

For example, the hydrogen ions are implanted at the positions Pb4, Pb3, Pb2, and Pb1, and the semiconductor substrate 10 is annealed under a first condition. As a result, peaks of the hydrogen chemical concentration distribution are formed at the positions Pb4, Pb3, Pb2, and Pb1. Subsequently, the hydrogen ions are implanted at the position Ps, the helium ions are implanted between the position Pb2 and the position Pb1, and the semiconductor substrate 10 is annealed under a second condition. An annealing temperature of the second condition is lower than that of the first condition. Most of the lattice defects generated by implanting the hydrogen ions at the positions Pb4, Pb3, Pb2, and Pb1 are terminated through annealing at a relatively high temperature. In contrast, as for the lattice defects generated by implanting the hydrogen ions at the position Ps, the lattice defects at the position Ps are terminated through annealing at a relatively low temperature. On the other hand, there is a large amount of hydrogen present also in the vicinity of the position Pb1, and thus the lattice defects generated by implanting the helium ions between the position Pb2 and the position Pb1 are terminated also in the vicinity of the position Pb1 while the lattice defect density has a peak between the position Pb2 and the position Pb1.

In this example, another peak of the hydrogen chemical concentration is not provided on a side from which the hydrogen ions have been implanted (the upper surface 21 side in this example) with respect to the peak of the hydrogen chemical concentration at the position Ps. On the other hand, another peak of the hydrogen chemical concentration (the position Pb1) is provided on a side from which the helium ions have been implanted (the lower surface 23 side in this example) with respect to the peak of the hydrogen chemical concentration at the position Pb2. An integrated value of the lattice defect density on the upper surface 21 side relative to the position Ps may be greater than an integrated value of the lattice defect density on the lower surface 23 side relative to the position Pb2. It should be noted that the lattice defect density at the position Kb may be defined as a helium chemical concentration.

The distribution diagram (D) shows a carrier lifetime distribution after the hydrogen ions are implanted into the semiconductor substrate 10 and then annealing is performed under a predetermined condition. The carrier lifetime distribution has a shape obtained by inverting the vertical axis of the lattice defect density distribution. For example, a position at which a carrier lifetime has a minimum value matches the center peak position Ks of the lattice defect density. It should be noted that the carrier lifetime of the semiconductor device 100 may have a maximum value τ₀ in a region within a range of the FW1% M centered on the peak position Ps of the hydrogen chemical concentration. The maximum value τ₀ may be for the carrier lifetime in the drift region 18 on the lower surface 23 side relative to the peak position Ps of the hydrogen chemical concentration. The carrier lifetime of the semiconductor device 100 may have the maximum value τ₀ in a region within a range of the FW1% M centered on each peak position Ps, Pb4, Pb3, Pb2, and Pb1 of the hydrogen chemical concentration.

The carrier lifetime may have a sufficiently great value τ₀ on the lower surface 23 side relative to the position Z0. The fact that the carrier lifetime has the sufficiently great value τ₀ may be for the carrier lifetime for a case where lifetime killers or defects mainly composed of vacancies or divacancies are not intentionally introduced into the semiconductor substrate 10. At the temperature of 300K, τ₀ may be 10 μs or greater, or may be 30 μs or greater. As an example, τ₀ is 10 μs. The carrier lifetime may be smaller than τ₀ at the position J₀ of the pn junction between the anode region 14 and the drift region 18 or the accumulation region 16.

The distribution diagram (E) shows a distribution of mobility of carriers after the hydrogen ions are implanted into the semiconductor substrate 10 and then annealing is performed under a predetermined condition. The mobility of carriers may be a mobility μ₀ for a case of an ideal crystal structure, on the lower surface 23 side relative to the position Z0. The mobility μ₀ is 1360 cm²/(Vs) for electrons and 495 cm²/(Vs) for holes in a case of silicon at the temperature of 300K, as an example. The mobility of carriers may be smaller than μ₀ at the position J₀ of the pn junction between the anode region 14 and the drift region 18 or the accumulation region 16.

A position at which the mobility of carriers has a minimum value may match the center peak position Ks of the lattice defect density. In addition, a position at which the mobility of carriers has a local minimum value matches the center peak position Kb of the lattice defect density. The mobility of carriers of the semiconductor device 100 may have the maximum value μ₀ in the region within the range of the FW1% M centered on each peak position Ps, Pb4, Pb3, Pb2, and Pb1 of the hydrogen chemical concentration.

The distribution diagram (F) shows a distribution of a carrier concentration after the hydrogen ions are implanted into the semiconductor substrate 10 and then annealing is performed under a predetermined condition. The carrier concentration can be measured by a spreading resistance profiling (an SR profiling method), as an example. The SR profiling method converts a spreading resistance into a resistivity, and calculates the carrier concentration from the resistivity. Assuming that the resistivity is ρ(Ω·cm), mobility is μ(cm²/(V·s)), an elementary charge is q(C), the carrier concentration is N(/cm³), it is expressed as N=1/(μqρ).

The SR profiling method uses, as the mobility of carriers, a value for a case where a crystalline state of the semiconductor substrate 10 is ideal. However, if a damage remains in the semiconductor substrate 10 due to ion implantation, the crystalline state of the semiconductor substrate 10 collapses into a disorder state, and the mobility has actually decreased. Originally, decreased mobility should be used as the mobility in the SR profiling, but it is difficult to measure a value of the decreased mobility. Therefore, the SR profiling in the example shown in the distribution diagram (F) has used an ideal value as the mobility. Therefore, the denominator of the expression for the carrier concentration described above increases, and the mobility decreases. In other words, in the distribution diagram (F), the measured carrier concentration has decreased overall in a region through which the hydrogen ions have passed (a region from a lower end of the anode region 14 to the high concentration region 26 of the semiconductor substrate 10). Note that, however, in the high concentration region 26 in the vicinity of the projected range Ps of the hydrogen ions, the hydrogen chemical concentration is high, and thus the disorder state is reduced by a hydrogen termination effect, and the mobility approaches a value for the crystalline state. Further, the hydrogen donors are also formed. Therefore, the carrier concentration is higher than the carrier concentration N₀ of the semiconductor substrate 10.

The measured carrier concentration has decreased overall in a region through which the hydrogen ions have passed (a region from the lower end of the anode region 14 to the vicinity of the position Ps of the semiconductor substrate 10). Note that, however, in the region on the lower surface 23 side relative to the position Pb4, the hydrogen chemical concentration is high overall, and thus the carrier concentration is higher than the substrate concentration N₀.

In the semiconductor device 100 in this example, the lattice defect density after annealing decreases before and after the peak position Ps of the hydrogen chemical concentration. Therefore, the carrier lifetime in the vicinity of the position Ps at which the hydrogen chemical concentration reaches a peak increases, and becomes approximately τ₀.

In addition, as an example, the hydrogen chemical concentration at the peak position Pb1 is the highest in the entire semiconductor substrate 10. When a maximum hydrogen chemical concentration value at the peak position Pb1 is 1×10¹⁵ atoms/cm³ or greater, a concentration of hydrogen diffusing on the upper surface 21 side increases. At this time, hydrogen will diffuse up to the position Ps. As a result, the dangling bonds due to vacancies or divacancies at the position Ps are terminated not only by hydrogen implanted at the position Ps from the upper surface 21 side at a maximum concentration, but also by hydrogen moved from a position of the position Pb1 through diffusion. As a result, the lattice defect density can be reliably set to Nr₀ in the vicinity of the peak of the doping concentration distribution at the position Ps, and the carrier lifetime at the position Ps can be set to τ0.

FIG. 11B illustrates another example of an enlarged cross sectional view in the vicinity of a second lifetime region 200. This example is different from the example shown in FIG. 10 in that hydrogen ions are implanted from a lower surface 23 side to an upper surface 21 side (for example, near an upper surface 21 or lower ends of trench portions) to form first lifetime regions 204. A distance T1 from a lower surface 23 to an end portion of a first lifetime region 204 on the upper surface 21 side may be greater than a value equivalent to half a thickness of a semiconductor substrate 10 in the Z axis direction. The distance T1 in this example corresponds to a thickness of the first lifetime region 204. Similarly to the example shown in FIG. 10, a distance in a depth direction from a depth position of a density peak of lattice defects 202 to an upper end of the first lifetime region 204 is defined as T1′. 2×T1′ may be used as the thickness T1 of the first lifetime region 204.

FIG. 11C shows each of a distribution diagram of a net doping concentration (A), a distribution diagram of a hydrogen chemical concentration (B), a distribution diagram of a lattice defect density (C), a distribution diagram of a carrier lifetime (D), a distribution diagram of carrier mobility (E), and a distribution diagram of a carrier concentration (F) along a line h-h in a semiconductor device 100 according to the embodiment example shown in FIG. 11B. On a buffer region 20 side of a drift region 18, at least one of a doping concentration or a carrier concentration may be higher than a bulk donor concentration. The buffer region 20 side of the drift region 18 refers to the buffer region 20 side relative to a center of the drift region 18 in a depth direction. In the example shown in FIG. 11C, a region where at least one of the doping concentration or the carrier concentration is higher than the bulk donor concentration is provided at a position that is in the drift region 18 and that is in contact with the buffer region 20.

FIG. 11D illustrates another example of an enlarged cross sectional view in the vicinity of a second lifetime region 200. This example is different from the examples shown in FIG. 10 and FIG. 11B in that first lifetime regions 204 are formed throughout from an upper surface 21 to a lower surface 23. The first lifetime regions 204 in this example may be formed by implanting hydrogen ions or helium from the upper surface 21 and passing them through the lower surface 23, or may be formed by implanting hydrogen ions or helium from the lower surface 23 and passing them through the upper surface 21. The first lifetime regions 204 in this example may be formed by radiating an electron beam. A thickness T1 of a first lifetime region 204 in this example is the same as a thickness of a semiconductor substrate 10. As an example, a width of a region where a density of lattice defects 202 has a value greater than or equal to a predetermined value may be defined as T1. The predetermined value for the density of the lattice defects 202 may be 1×10¹⁴/cm³. The predetermined value for the density of the lattice defects 202 may be a value for a doping concentration in a drift region 18. As another example, a width of a region where a carrier concentration by an SR profiling is lower than the doping concentration in the drift region 18 may be defined as T1. The doping concentration in the drift region 18 may be a bulk donor concentration, may be a concentration equivalent to a difference between the bulk donor concentration and a bulk acceptor concentration, may have a value obtained by adding the bulk donor concentration and a hydrogen donor concentration, or may have a value obtained by adding the concentration equivalent to the difference between the bulk donor concentration and the bulk acceptor concentration, and the hydrogen donor concentration.

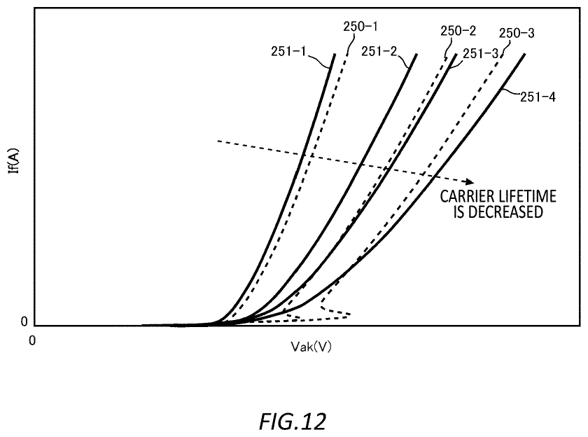

FIG. 12 illustrates examples of V-I characteristics during forward conduction of a diode portion 80. Characteristics 250 shown in FIG. 12 are the same as the characteristics in the comparative example shown in FIG. 4. In the comparative example, no second lifetime region 200 is provided. Characteristics 251 shown in FIG. 12 are characteristics in an example where one second lifetime region 200 is provided in one diode portion 80, as described in FIG. 5 to FIG. 9. In the examples of the characteristics 251, a width W1 of the second lifetime region 200 is 8 μm, a thickness T1 of a first lifetime region 204 is 30 μm, and a ratio W1/T1 is approximately 0.27. A characteristic 250-1 and a characteristic 251-1 have the same carrier lifetime in the first lifetime region 204, a characteristic 250-2 and a characteristic 251-2 have the same carrier lifetime in the first lifetime region 204, and a characteristic 250-3 and a characteristic 251-3 have the same carrier lifetime in the first lifetime region 204. As shown in FIG. 12, providing the second lifetime region 200 has been able to suppress snapback even if a carrier lifetime in the first lifetime region 204 is decreased. As a result, it is possible to reduce a reverse recovery loss in the diode portion 80 while suppressing the snapback.

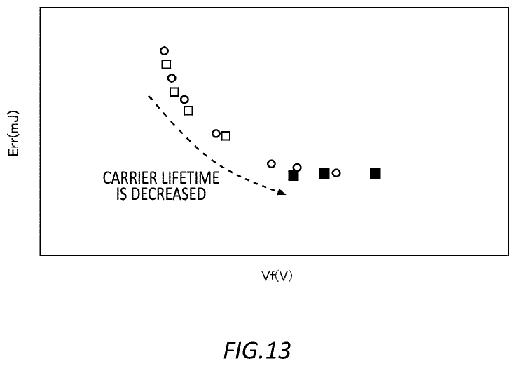

FIG. 13 illustrates trade-off characteristics between a forward voltage Vf and a reverse recovery loss Err in a diode portion 80. Plots indicated by circles in FIG. 13 are characteristics for a case where one second lifetime region 200 is provided in one diode portion 80, as described in FIG. 5 to FIG. 9. Plots indicated by squares in FIG. 13 are characteristics for a case where no second lifetime region 200 is provided. In the examples indicated by black squares, snapback has occurred.

As shown in FIG. 13, even if the second lifetime region 200 is provided, it is possible to obtain trade-off characteristics equal to those obtained when no second lifetime region 200 is provided. In addition, even in a region where a carrier lifetime is short, providing the second lifetime region 200 has been able to suppress occurrence of the snapback.

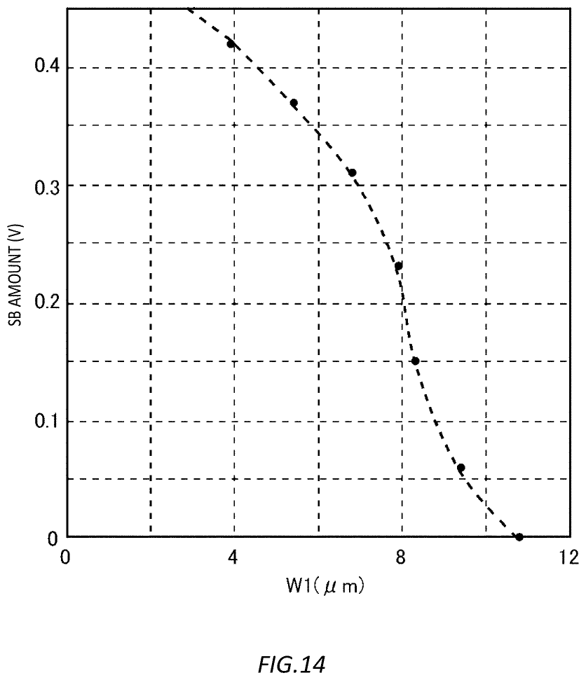

FIG. 14 illustrates a relationship between a width W1 of a second lifetime region 200 and a snapback amount (an SB amount). In this example, one second lifetime region 200 is provided in one diode portion 80, as described in FIG. 5 to FIG. 9. A thickness T1 of a first lifetime region 204 in this example is 30 μm. It can be seen that increasing the width W1 of the second lifetime region 200 decreases the snapback amount. Especially, when the width W1 of the second lifetime region 200 exceeds 7 μm, the snapback amount significantly decreases, and when the width W1 becomes 11 μm or greater, the snapback amount becomes 0.

The width W1 of the second lifetime region 200 may be 7 μm or greater. The width W1 may be 8 μm or greater, may be 10 μm or greater, or may be 11 μm or greater. A ratio W1/T1 of the width W1 of the second lifetime region 200 to the thickness T1 of the first lifetime region 204 may be 0.23 or greater, may be 0.27 or greater, may be 0.33 or greater, or may be 0.37 or greater. In addition, the width W1 of the second lifetime region may be 12 μm or smaller. The ratio W1/T1 may be 0.4 or smaller.

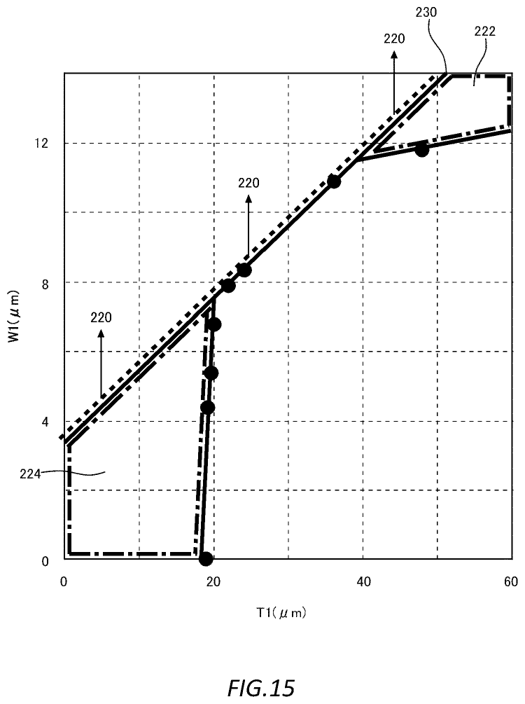

FIG. 15 illustrates whether snapback has occurred when a thickness T1 of a first lifetime region 204 and a width W1 of a second lifetime region 200 are changed. Plots indicated by circle marks in FIG. 15 show a boundary example where the snapback does not occur. The snapback has not occurred in regions 220, 222, and 224 where the width W1 is greater (or the thickness T1 is smaller) than the one at the boundary example.

Note that, however, in the region 222, the thickness T1 of the first lifetime region 204 is great, and thus an IE effect will decrease, and a forward voltage Vf will be too high. In the region 224, the thickness T1 of the first lifetime region 204 is small, and thus the IE effect will increase also in a low current operation region, and the forward voltage Vf will be too low. Therefore, it is preferable to set the thickness T1 of the first lifetime region 204 and the width W1 of the second lifetime region 200 within a range of the region 220. The region 220 is a region where the width W1 is greater than a width W (μm) defined by a straight line 230. The straight line 230 is given by Expression 1:

W=0.21×T1+3.3 (1).

As described above, when the thickness T1 of the first lifetime region 204 is too great, the IE effect decreases. The thickness T1 may be smaller than a thickness of a drift region 18 in a depth direction (the Z axis direction). In addition, the thickness T1 may be 100 μm or smaller, may be 60 μm or smaller, or may be 40 μm or smaller. The thickness T1 is greater than 0. Note that, however, when the thickness T1 is too small, the IE effect will increase also in the low current operation region, and the forward voltage Vf will be too low. The thickness T1 may be 10 μm or greater, may be 15 μm or greater, or may be 20 μm or greater.

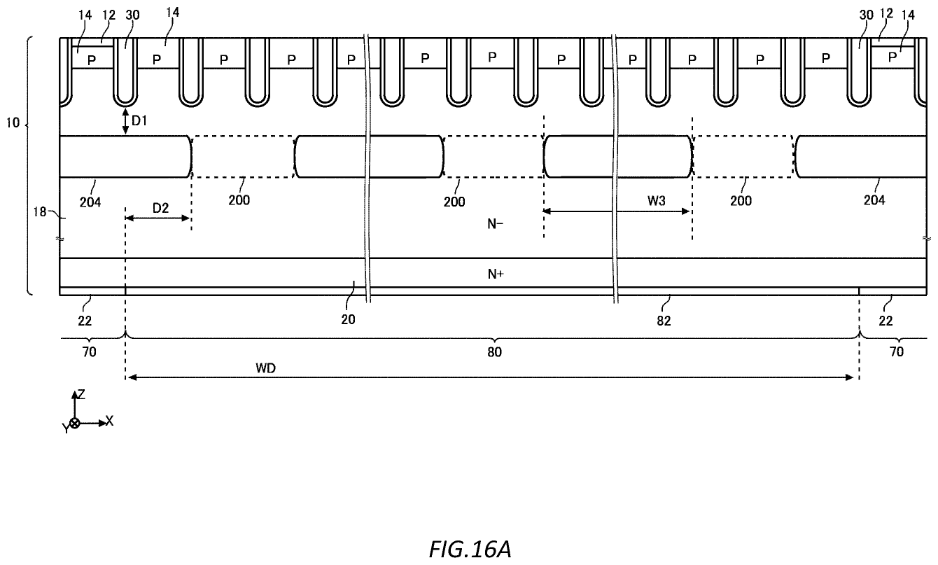

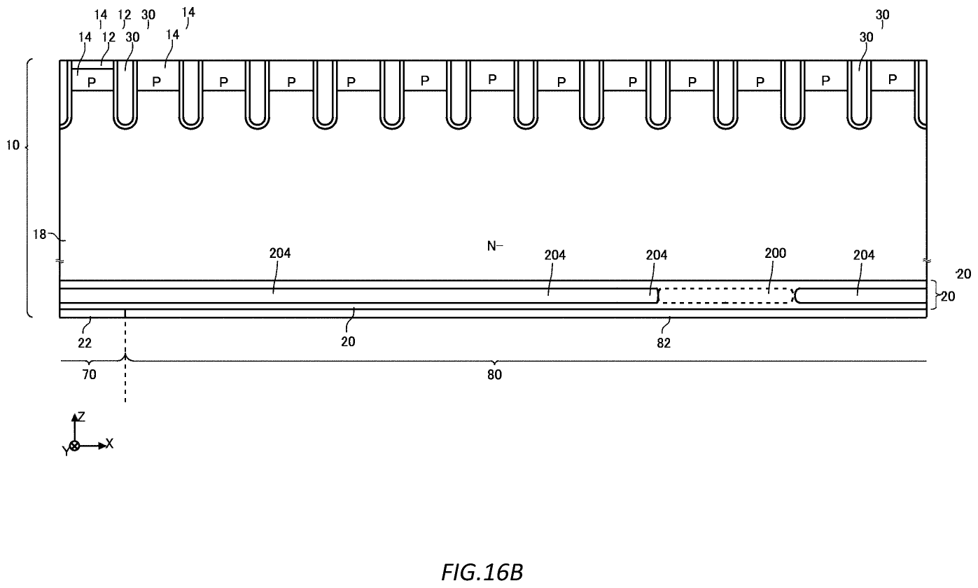

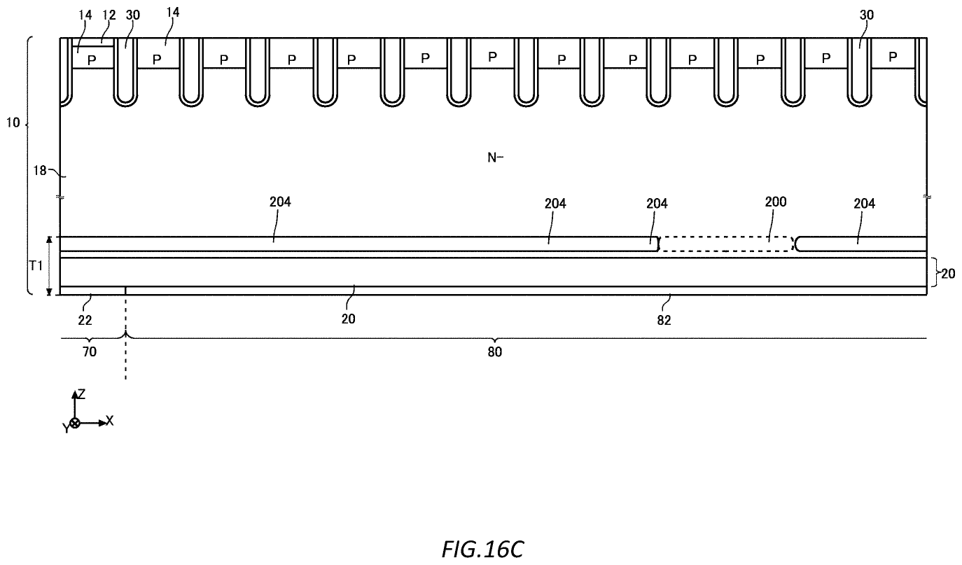

FIG. 16A illustrates another arrangement example of a first lifetime region 204 and a second lifetime region 200 in a diode portion 80. Except for an arrangement of a first lifetime region 204 and a second lifetime region 200, this example has an aspect similar to any aspect described in FIG. 1 to FIG. 15.

A semiconductor device 100 in this example includes two or more second lifetime regions 200 in one diode portion 80. The respective second lifetime regions 200 are spaced apart from each other in a first direction (the X axis direction in this example). A first lifetime region 204 is arranged between two second lifetime regions 200. A width W1 of each of the second lifetime regions 200 may be the same as the width W1 described in FIG. 1 to FIG. 15. Providing the two or more second lifetime regions 200 can uniformize an electron density above first lifetime regions 204. Electrons can be dispersed over and passed through a plurality of second lifetime regions 200.

It should be noted that, in each of the examples described in FIG. 1 to FIG. 16A, a sum of widths W1 of one or more second lifetime regions 200 included in one diode portion 80 in the first direction (the X axis direction in this example) may be 0.1 times or less a width WD of one diode portion 80 in the first direction. When the sum of the widths W1 is too great, a turn-off time of the diode portion 80 will be longer, and a reverse recovery loss will increase. The sum of the widths W1 may be 0.05 times or less the width WD. The sum of the widths W1 may be 0.001 times or more, or may be 0.01 times or more, the width WD.

The diode portion 80 has a plurality of trench portions (dummy trench portions 30 in this example) arranged above the first lifetime regions 204. A distance D2 between a second lifetime region 200 and a transistor portion 70 in the first direction (the X axis direction in this example) may be greater than or equal to a distance D1 between a lower end of a trench portion (a dummy trench portion 30 in this example) and the first lifetime region 204 in a second direction (the Z axis direction in this example). The trench portion may be a dummy trench portion 30 closest to the transistor portion 70 among a plurality of dummy trench portions 30 in the diode portion 80. An end portion of the transistor portion 70 in the X axis direction is a boundary portion between a collector region 22 and a cathode region 82. Ensuring the distance D2 can suppress the electrons implanted from the cathode region 82 from expanding up to the transistor portion 70, and can restrain the electrons from escaping to an emitter electrode 52 through a n type channel formed in a base region 14 of the transistor portion 70. The distance D2 may be 1.5 times or more, or may be twice or more, the distance D1.

The two or more second lifetime regions 200 may be arranged at regular intervals in the first direction. In another example, an interval W3 between the second lifetime regions 200 may be smaller than the distance D2. This configuration can also increase the distance D2. In this example, the interval W3 between the second lifetime regions 200 is a width of the first lifetime region 204 in the first direction. Any of the second lifetime regions 200 may be arranged at a center of the diode portion 80 in the first direction. As a result, electrons or holes will be symmetrically implanted with respect to the center of the diode portion 80, and a carrier concentration in the diode portion 80 will have a substantially uniform distribution.

FIG. 16B illustrates another arrangement example of a first lifetime region 204 and a second lifetime region 200 in a diode portion 80. This example is different from the example shown in FIG. 16A in that first lifetime regions 204 and a second lifetime region 200 are formed on a lower surface 23 side. The first lifetime regions 204 and the second lifetime region 200 may be formed in a buffer region 20, may be formed in both the buffer region 20 and a cathode region 82, or may be formed in both the buffer region 20 and a collector region 22. Similarly to the example shown in FIG. 11B, a distance in a depth direction from a depth position of a density peak of lattice defects 202 to an upper end of a first lifetime region 204 is defined as T1′. 2×T1′ may be used as a thickness T1 of the first lifetime region 204. As a result, electrons or holes are uniformly implanted in a first direction, and snapback can be suppressed.

FIG. 16C illustrates another arrangement example of a first lifetime region 204 and a second lifetime region 200 in a diode portion 80. This example is different from the example shown in FIG. 16B in that first lifetime regions 204 and a second lifetime region 200 are formed on a lower surface 23 side of a drift region 18. A distance T1 from a lower surface 23 to an end portion of a first lifetime region 204 on an upper surface side may be smaller than a value equivalent to half a thickness of a semiconductor substrate 10 in the Z axis direction. When the first lifetime regions 204 are formed by implanting hydrogen ions or the like from the lower surface 23, the distance T1 corresponds to a thickness of the first lifetime region 204. Similarly to the example shown in FIG. 11B, a distance in a depth direction from a depth position of a density peak of lattice defects 202 to an upper end of the first lifetime region 204 is defined as T1′. 2×T1′ may be used as the thickness T1 of the first lifetime region 204.

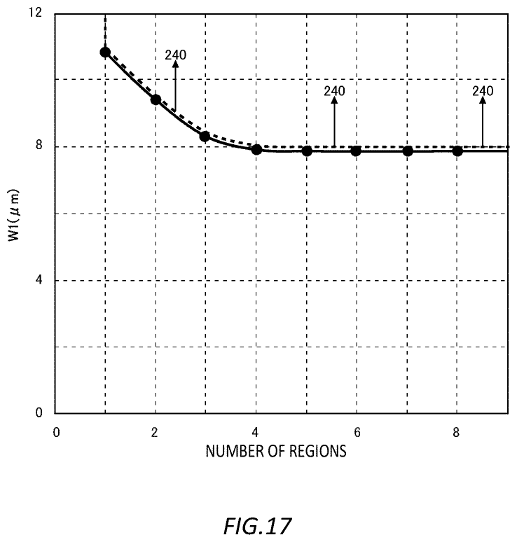

FIG. 17 illustrates whether snapback has occurred when the number of second lifetime regions 200 included in one diode portion 80 and a width W1 of each of the second lifetime regions 200 are changed. Plots indicated by circle marks in FIG. 17 show a boundary example where the snapback does not occur. The snapback has not occurred in a region 240 where the width W1 is greater than the one at the boundary example. When a plurality of second lifetime regions 200 are provided, the plurality of second lifetime regions 200 are arranged at regular intervals in a first direction. In this example, a thickness T1 of a first lifetime region 204 is 30 μm.

When the number of second lifetime regions 200 (the number of regions on the horizontal axis in FIG. 17) is increased, there is a tendency that the snapback tends can be suppressed even if the width W1 of a second lifetime region 200 is decreased. Note that, however, even if the number of second lifetime regions 200 is greater than four, the width W1 of the second lifetime region 200 required to prevent the snapback has not been decreased.

The width W1 of one second lifetime region 200 may be 8 μm or greater. The width W1 may be 0.27 times or more the thickness T1 of the first lifetime region 204. In addition, even when only one second lifetime region 200 is provided in one diode portion 80, the width W1 of approximately 12 μm has been able to suppress the snapback. The width W1 may be 12 μm or smaller. The width W1 may be 0.4 times or less the thickness T1 of the first lifetime region 204.

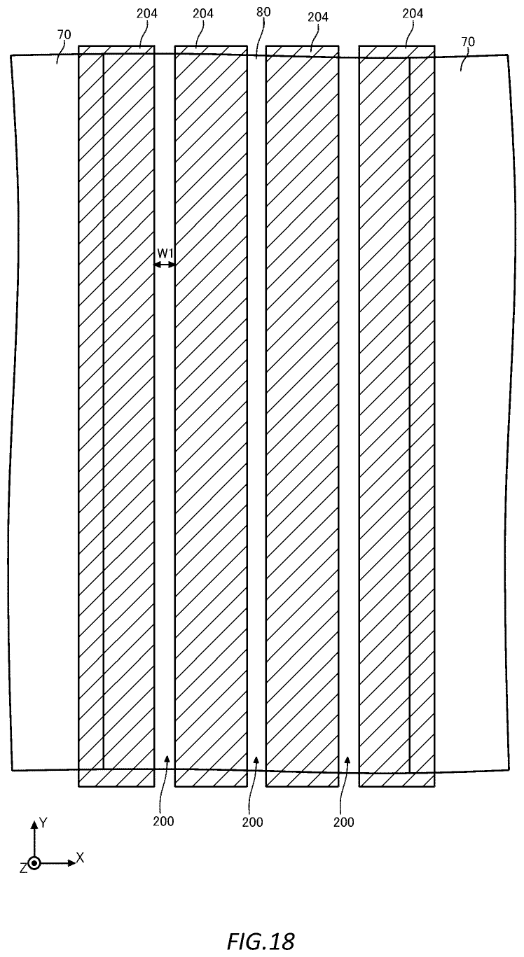

FIG. 18 illustrates an arrangement example of a first lifetime region 204 and a second lifetime region 200 in an XY plane. First lifetime regions 204 and second lifetime regions 200 in this example are provided in a striped pattern with a longitudinal length in a third direction (the Y axis direction in this example) parallel to an upper surface 21 of a semiconductor substrate 10 and perpendicular to a first direction (the X axis direction in this example). The first lifetime regions 204 and the second lifetime regions 200 may have the same length as that of a cathode region 82 in the Y axis direction, or may be longer than the cathode region 82.

In this example, a diode portion 80 and a transistor portion 70 are arranged side by side in the first direction (the X axis direction). In addition, as shown in FIG. 2 or the like, respective trench portions (gate trench portions 40 and dummy trench portions 30) are spaced apart from each other in the first direction (the X axis direction). In this example, a longitudinal direction of the first lifetime regions 204 and the second lifetime regions 200 is the same as a longitudinal direction of the trench portions. In addition, the longitudinal direction of the first lifetime regions 204 and the second lifetime regions 200 is the same as a longitudinal direction of the diode portion 80 (or the cathode region 82).

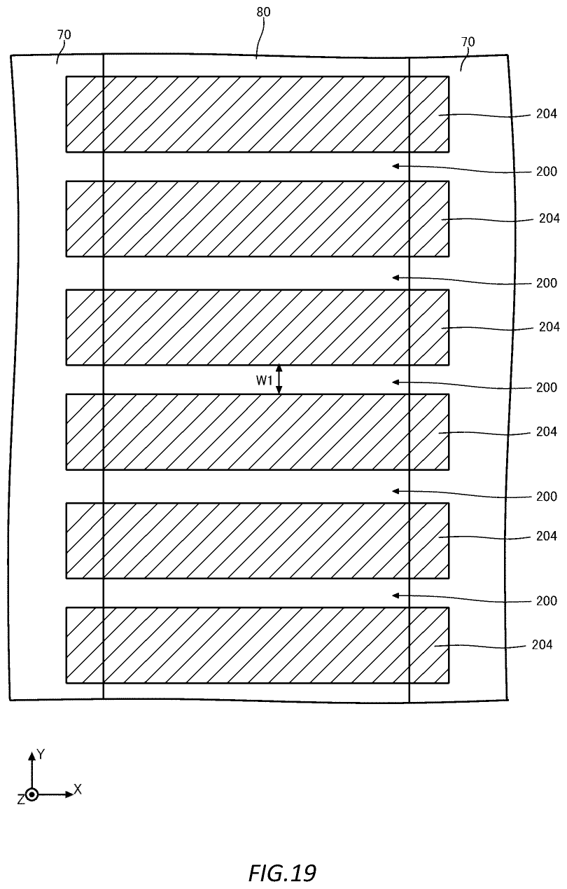

FIG. 19 illustrates another arrangement example of a first lifetime region 204 and a second lifetime region 200 in an XY plane. In this example the Y axis direction is a first direction, and the X axis direction is a third direction. In other words, first lifetime regions 204 and second lifetime regions 200 in this example are arranged side by side in the Y axis direction. The first lifetime regions 204 and the second lifetime regions 200 in this example are provided in a striped pattern with a longitudinal length in the X axis direction (the third direction). The first lifetime regions 204 and the second lifetime regions 200 may have the same length as that of a diode portion 80 in the X axis direction, or may be longer than the diode portion 80.

In this example, a diode portion 80 and a transistor portion 70 are arranged side by side in the third direction (the X axis direction). In addition, respective trench portions (gate trench portions 40 and dummy trench portions 30) are spaced apart from each other in the third direction (the X axis direction). In this example, a longitudinal direction of the first lifetime regions 204 and the second lifetime regions 200 is orthogonal to a longitudinal direction of the trench portions. In addition, the longitudinal direction of the first lifetime regions 204 and the second lifetime regions 200 is orthogonal to a longitudinal direction of the diode portion 80 (or a cathode region 82). This arrangement can also reduce a reverse recovery loss of the diode portion 80 while suppressing snapback.

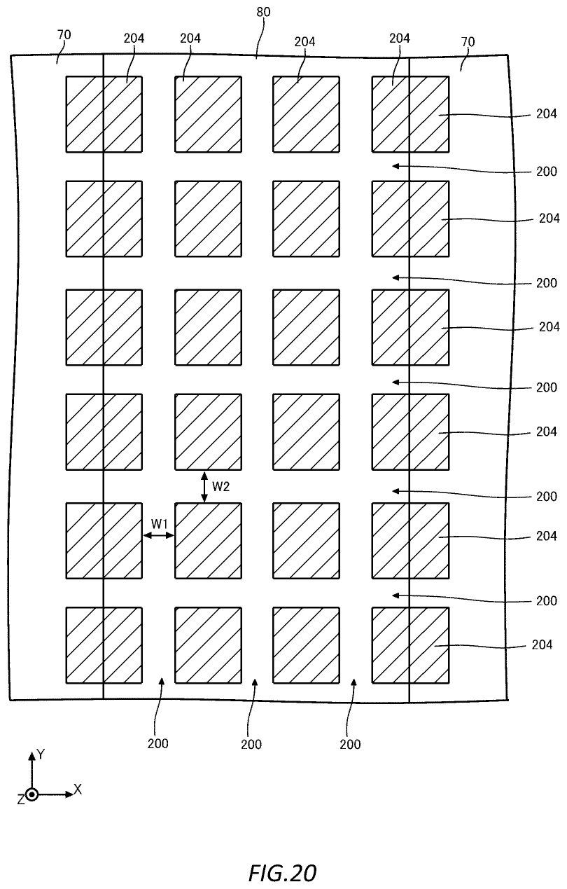

FIG. 20 illustrates another arrangement example of a first lifetime region 204 and a second lifetime region 200 in an XY plane. A second lifetime region 200 in this example is sandwiched between first lifetime regions 204 also in a third direction (the Y axis direction in this example) parallel to an upper surface 21 of a semiconductor substrate 10 and perpendicular to a first direction (the X axis direction in this example).

As an example, a plurality of first lifetime regions 204 may be discretely arranged in both the X axis direction and the Y axis direction. In the example shown in FIG. 20, the first lifetime regions 204, which are rectangular in a top view, are discretely arranged along both the X axis direction and the Y axis direction. The second lifetime region 200 in this example has a latticed pattern in which a portion extending in the X axis direction intersects with a portion extending in the Y axis direction in a top view.

In another example, a plurality of second lifetime regions 200 may be discretely arranged in both the X axis direction and the Y axis direction. For example, the second lifetime regions 200, which are rectangular in a top view, may be discretely arranged along both the X axis direction and the Y axis direction.

In this example, a width of the second lifetime region 200 in the Y axis direction is defined as W2. The width W2 may satisfy a condition similar to those for the width W1 described in FIG. 1 to FIG. 19. For example, the width W2 is 0.2 times or more a thickness T1 of a first lifetime region 204. Note that, however, the width W2 and the width W1 may not be the same. The width W1 and the width W2 may have different values within a range of the conditions for the width W1 described in FIG. 1 to FIG. 19. This configuration can also reduce a reverse recovery loss of a diode portion 80 while suppressing snapback.

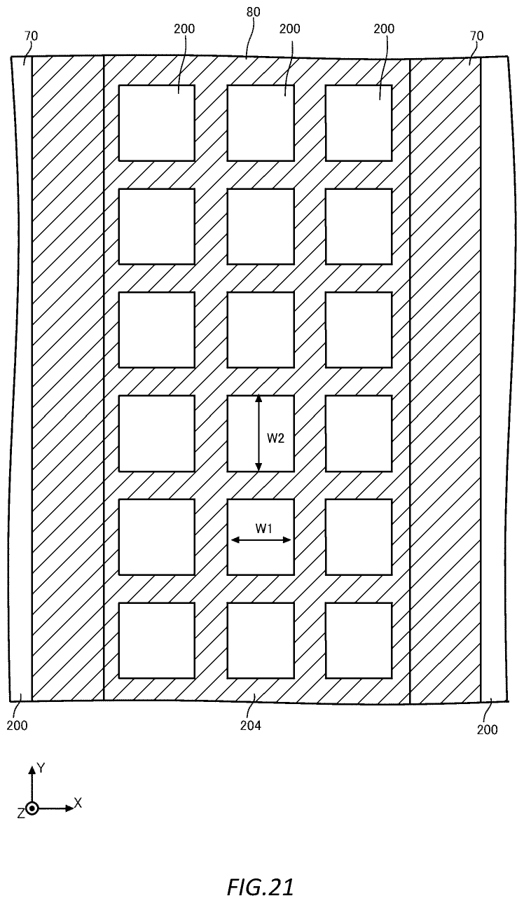

FIG. 21 illustrates another arrangement example of a first lifetime region 204 and a second lifetime region 200 in an XY plane. A first lifetime region 204 in this example is sandwiched between second lifetime regions 200 in both a first direction (the X axis direction in this example) parallel to an upper surface 21 of a semiconductor substrate 10 and a third direction (the Y axis direction in this example).

As an example, a plurality of second lifetime regions 200 may be discretely arranged in both the X axis direction and the Y axis direction. In the example shown in FIG. 21, second lifetime regions 200, which are rectangular in a top view, are discretely arranged along both the X axis direction and the Y axis direction. The first lifetime region 204 in this example has a latticed pattern in which a portion extending in the X axis direction intersects with a portion extending in the Y axis direction in a top view. This configuration can also reduce a reverse recovery loss of a diode portion 80 while suppressing snapback.

A second lifetime region 200 may be arranged in a first lifetime region 204 of the diode portion 80. A second lifetime region 200 may be or may not be arranged in the first lifetime region 204 of a transistor portion 70. The fact that the second lifetime region 200 is arranged in the first lifetime region 204 refers to that the second lifetime region 200 is enclosed by the first lifetime region 204 in a top view. In the transistor portion 70, a ratio of an area S2_t of the second lifetime region 200 enclosed by the first lifetime region 204 to an area S1_t of the first lifetime region 204 is defined as S2_t/S1_t. In the diode portion 80, a ratio of an area S2_d of the second lifetime region 200 enclosed by the first lifetime region 204 to an area S1_d of the first lifetime region 204 is defined as S2_d/S1_d. The ratio S2_t/S1_t may be smaller than the ratio S2_d/S1_d. The ratio S2_t/S1_t may be smaller than or equal to 50%, may be smaller than or equal to 20%, or may be smaller than or equal to 10%, of the ratio S2_d/S1_d. The area S2_t may be 0. When a body diode of the transistor portion 70 is energized, relatively many carriers are implanted, but making the second lifetime region 200 in the first lifetime region 204 of the transistor portion 70 small or not providing it can shorten a lifetime of the carriers.

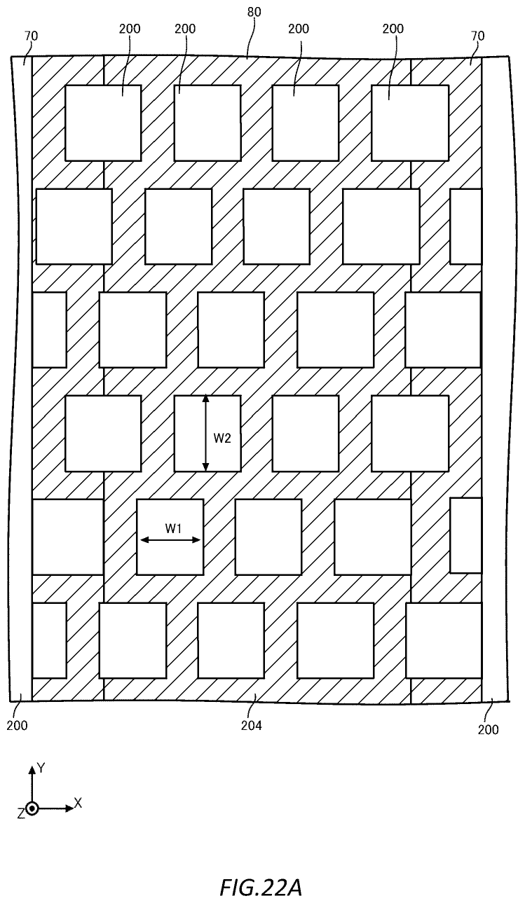

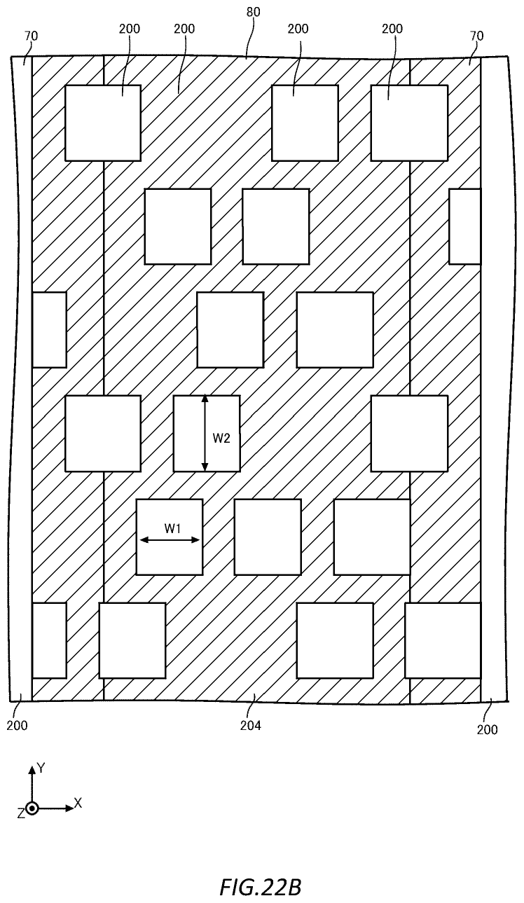

FIG. 22A illustrates another arrangement example of a first lifetime region 204 and a second lifetime region 200 in an XY plane. This example is different from the example shown in FIG. 21 in an arrangement of a plurality of second lifetime regions 200. Except for that, this example has a structure similar to the one in the example shown in FIG. 21.

In the example shown in FIG. 21, the plurality of second lifetime regions 200 are arranged side by side in the X axis direction and the Y axis direction. In the example shown in FIG. 22A, a plurality of second lifetime regions 200 are arranged side by side along two directions different from both the X axis and the Y axis. This configuration can also reduce a reverse recovery loss of a diode portion 80 while suppressing snapback.

A second lifetime region 200 may be arranged in a first lifetime region 204 of the diode portion 80. A second lifetime region 200 may be or may not be arranged in the first lifetime region 204 of a transistor portion 70. This configuration can also reduce the reverse recovery loss of the diode portion 80 while suppressing the snapback.

FIG. 22B illustrates another arrangement example of a first lifetime region 204 and a second lifetime region 200 in an XY plane. This example is different from the example shown in FIG. 22A in an arrangement of a plurality of second lifetime regions 200. The arrangement of the plurality of second lifetime regions 200 may not be symmetrical, and may be random.

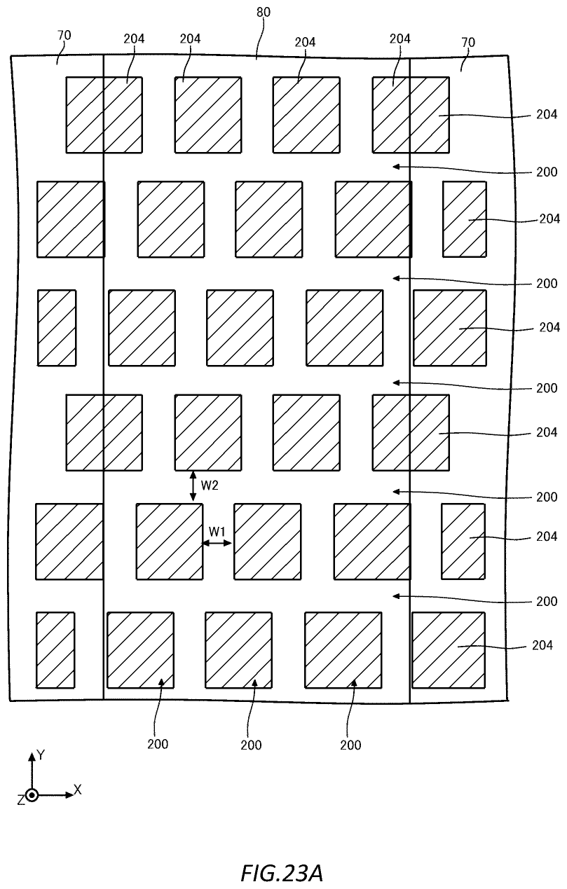

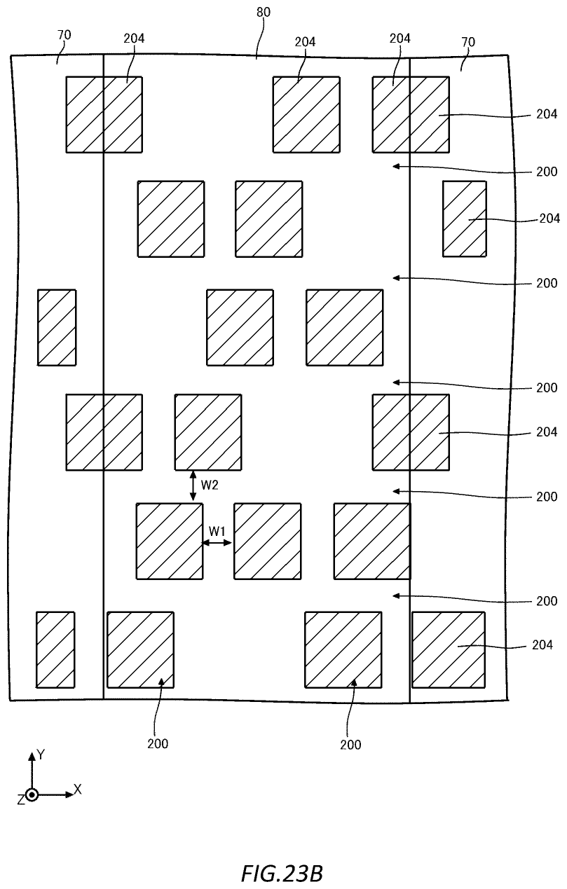

FIG. 23A illustrates another arrangement example of a first lifetime region 204 and a second lifetime region 200 in an XY plane. This example is different from the example shown in FIG. 20 in an arrangement of a plurality of first lifetime regions 204. Except for that, this example has a structure similar to the one in the example shown in FIG. 20.

In the example shown in FIG. 20, the plurality of first lifetime regions 204 are arranged side by side in the X axis direction and the Y axis direction. In the example shown in FIG. 23A, a plurality of first lifetime regions 204 are arranged side by side along two directions different from both the X axis and the Y axis. This configuration can also reduce a reverse recovery loss of a diode portion 80 while suppressing snapback.

A second lifetime region 200 in this example has a latticed pattern in which a portion extending in the X axis direction intersects with a portion extending in the Y axis direction in a top view. Widths in directions orthogonal to extending directions of the second lifetime region 200 may be used as widths W1 and W2 of the second lifetime region 200. In this example, a width in the X axis direction of the second lifetime region 200 extending in the Y axis direction is defined as W1, and a width in the Y axis direction of the second lifetime region 200 extending in the X axis direction is defined as W2.

FIG. 23B illustrates another arrangement example of a first lifetime region 204 and a second lifetime region 200 in an XY plane. This example is different from the example shown in FIG. 23A in an arrangement of a plurality of first lifetime regions 204. The arrangement of the plurality of first lifetime regions 204 may not be symmetrical, and may be random.

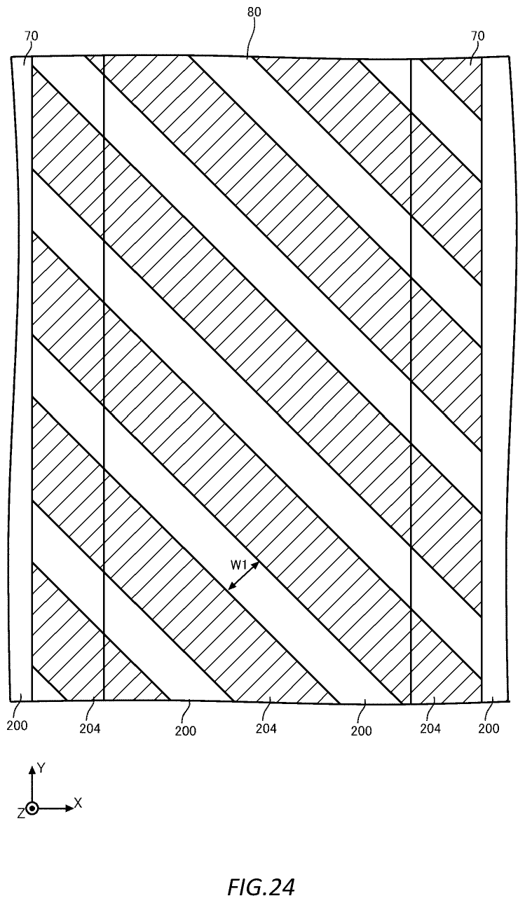

FIG. 24 illustrates another arrangement example of a first lifetime region 204 and a second lifetime region 200 in an XY plane. In this example, extending directions of a first lifetime region 204 and a second lifetime region 200 are different from both the X axis direction and the Y axis direction. Except for that, this example has a structure similar to the one in any aspect described in the present specification.

In this example, first lifetime regions 204 and second lifetime regions 200 are alternately arranged along a first direction orthogonal to an extending direction of each lifetime region. The first direction in this example is different from both the X axis direction and the Y axis direction. Trench portions of a transistor portion 70 and a diode portion 80 are provided extending (in other words, having a longitudinal length) in the Y axis direction. Therefore, each of a plurality of trench portions extends in a direction at an angle greater than 0 degree and smaller than 90 degrees with respect to the first direction at an upper surface 21 of a semiconductor substrate 10. The angle may be 15 degrees or greater, may be 30 degrees or greater, or may be 45 degrees or greater. The angle may be 75 degrees or smaller, may be 60 degrees or smaller, or may be 45 degrees or smaller. This configuration can also reduce a reverse recovery loss of a diode portion 80 while suppressing snapback.

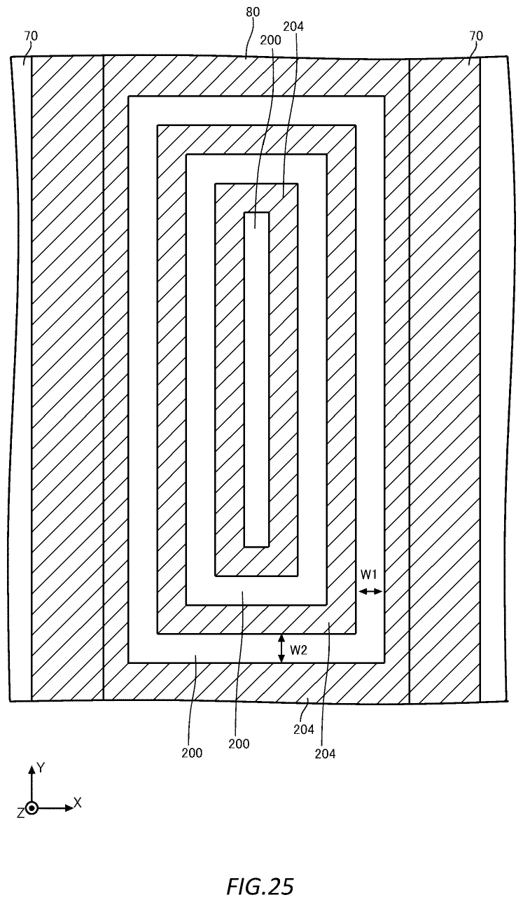

FIG. 25 illustrates another arrangement example of a first lifetime region 204 and a second lifetime region 200 in an XY plane. In this example, first lifetime regions 204 which are annular and second lifetime regions 200 which are annular are alternately arranged concentrically. In this example, a width in the X axis direction of a second lifetime region 200 extending in the Y axis direction is defined as W1, and a width in the Y axis direction of a second lifetime region 200 extending in the X axis direction is defined as W2.

A second lifetime region 200 may be arranged in a first lifetime region 204 of a diode portion 80. A second lifetime region 200 may be or may not be arranged in the first lifetime region 204 of a transistor portion 70. This configuration can also reduce a reverse recovery loss of the diode portion 80 while suppressing snapback.

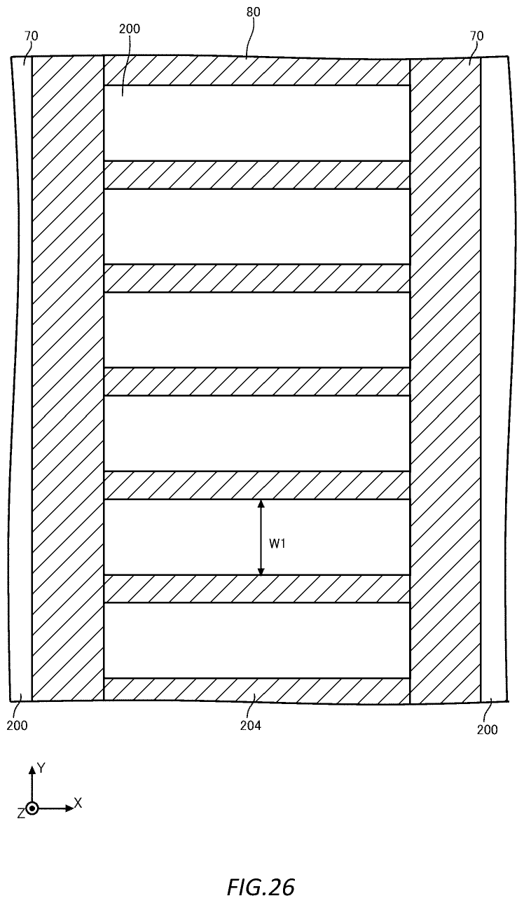

FIG. 26 illustrates another arrangement example of a first lifetime region 204 and a second lifetime region 200 in an XY plane. In this example the Y axis direction is a first direction, and the X axis direction is a third direction. In other words, first lifetime regions 204 and second lifetime regions 200 in this example are arranged side by side in the Y axis direction.

The first lifetime regions 204 and the second lifetime regions 200 in this example are partially provided in a striped pattern with a longitudinal length in the X axis direction (the third direction). Both end portions of the first lifetime regions 204 in this example in the X axis direction are arranged in a transistor portion 70. Both end portions of the second lifetime regions 200 in this example in the X axis direction are arranged in a diode portion 80 or at a boundary between the diode portion 80 and the transistor portion 70. This arrangement can also reduce a reverse recovery loss of the diode portion 80 while suppressing snapback.

In each of the examples described in FIG. 1 to FIG. 26, the width W1 and the width W2 of the second lifetime region 200 may be greater than or equal to 3% of a diffusion length of carriers in the semiconductor substrate 10. The diffusion length of carriers in the semiconductor substrate 10 may be, for example, a diffusion length of carriers in a region where lifetime control is not performed. The region where the lifetime control is not performed may be, for example, the drift region 18 which is neither the first lifetime region 204 nor the second lifetime region 200 among the drift regions 18. The diffusion length of carriers may be a diffusion length of electrons, may be a diffusion length of holes, or may be a bipolar diffusion length. As described above, the electrons may be attached to the lattice defects 202 in the first lifetime regions 204 on both sides of the second lifetime region 200 when the electrons pass through the second lifetime region 200. It is possible to suppress the electrons from being attached to the lattice defects 202 by setting a ratio of the width W1 and the width W2 of the second lifetime region 200 to the diffusion length of electrons to a ratio greater than or equal to a predetermined ratio.

A diffusion length of electrons Lₙ is given by Expression 2:

Lₙ=(Dₙτₙ)^{0.5} (2),
where Dₙ is a diffusion coefficient of electrons (cm²/s), and τₙ is a lifetime of electrons (s). The diffusion coefficient Dₙ is given by Expression 3:

Dₙ=(k_{B}Tμₙ)/q (3),
where k_{B} is a Boltzmann constant (1.38×10⁻²³(J/K)), T is a temperature (K), μₙ is mobility of electrons (cm²/Vs) in the semiconductor substrate 10, and q is an elementary charge (1.60×10⁻¹⁹(C)). A diffusion length of holes Lₚ is given by Expression 4:

Lₚ=(Dₚτₚ)^{0.5} (4),
where Dₚ is a diffusion coefficient of holes (cm²/s), and τₚ is a lifetime of electrons (s). The diffusion coefficient Dₚ is given by Expression 5:

Dₚ=(k_{B}Tμₚ)/q (5),
where μₚ is mobility of holes (cm²/Vs) in the semiconductor substrate 10. The bipolar diffusion length is given by Expression 6:

Lₐ=(Dₐτ_{HL})^{0.5} (6),
where Dₐ is a bipolar diffusion coefficient (cm²/s), and Dₐ=2DₙDₚ/(Dₙ+Dₚ) is established. τ_{HL} is a high implantation level lifetime (s), and τ_{HL}=τₙ+τₚ is established. When the semiconductor substrate 10 is a silicon substrate and when the temperature T is −40 degrees C., τₙ may be 1×10⁻⁵ (s), μₙ may be 2600 (cm²/Vs), Dₙ may be 52.25 (cm²/s), and Lₙ may be 230 (μm). When the semiconductor substrate 10 is a silicon substrate and when the temperature T is −40 degrees C., τₚ is 1×10⁻⁵ (s), μₚ is 860 (cm²/Vs), Dₚ is 17.36 (cm²/s), and Lₚ is 126 (μm). When the semiconductor substrate 10 is a silicon substrate and when the temperature T is −40 degrees C., τ_{HL} may be 2×10⁻⁵ (s), Dₐ may be 26.06 (cm²/s), and Lₐ may be 228.3 (μm). The width W1 and the width W2 of the second lifetime region 200 may be greater than or equal to 3%, or may be greater than or equal to 4%, of the diffusion length of carriers in the semiconductor substrate 10.

While the present invention has been described by way of the embodiments, the technical scope of the present invention is not limited to the scope described in the above-described embodiments. It is apparent to persons skilled in the art that various alterations or improvements can be made to the above-described embodiments. It is apparent from the description of the claims that embodiments added with such alterations or improvements can also be included in the technical scope of the present invention.

It should be noted that the operations, procedures, steps, stages, and the like of each process performed by an apparatus, system, program, and method shown in the claims, embodiments, or diagrams can be performed in any order as long as the order is not indicated by “prior to,” “before,” or the like and as long as the output from a previous process is not used in a later process. Even if the operation flow is described using phrases such as “first” or “next” in the claims, embodiments, or diagrams for convenience, it does not necessarily mean that the process must be performed in this order.

What is claimed is:

1. A semiconductor device comprising:
a semiconductor substrate having an upper surface and a lower surface and provided with a drift region of a first conductivity type; and
a diode portion provided in the semiconductor substrate, wherein
the diode portion has:
a base region of a second conductivity type provided between the drift region and the upper surface of the semiconductor substrate;
a first lifetime region arranged in the drift region on a side of the lower surface of the semiconductor substrate relative to the base region; and
a second lifetime region which is arranged to be sandwiched between first lifetime regions including the first lifetime region in a first direction parallel to the upper surface of the semiconductor substrate and in which a carrier lifetime is longer than in the first lifetime region, and
a width of the second lifetime region in the first direction is greater than a width W (μm) indicated by Expression 1:
W=0.21×T1+3.3 (1),
wherein T1 is a thickness (μm) of the first lifetime region in a second direction perpendicular to the upper surface.

2. The semiconductor device according to claim 1, wherein
the width of the second lifetime region in the first direction is 7 μm or greater.

3. The semiconductor device according to claim 1, wherein
the width of the second lifetime region in the first direction is 12 μm or smaller.

4. The semiconductor device according to claim 1, wherein
the diode portion has one or more second lifetime regions including the second lifetime region,
a sum of widths of the one or more second lifetime regions in the first direction is 0.1 times or less a width of the diode portion in the first direction.

5. The semiconductor device according to claim 1, further comprising
a transistor portion provided in the semiconductor substrate and arranged side by side with the diode portion in the first direction.

6. The semiconductor device according to claim 5, wherein
the diode portion and the transistor portion have a plurality of trench portions spaced apart from each other in the first direction.

7. The semiconductor device according to claim 1, further comprising
a transistor portion provided in the semiconductor substrate and arranged side by side with the diode portion in a third direction parallel to the upper surface of the semiconductor substrate and perpendicular to the first direction.

8. The semiconductor device according to claim 7, wherein
the diode portion and the transistor portion have a plurality of trench portions spaced apart from each other in the third direction.

9. The semiconductor device according to claim 6, wherein
at least some of the trench portions of the diode portion are arranged above the first lifetime region, and
a distance between the second lifetime region and the transistor portion in the first direction is greater than or equal to a distance between a lower end of a trench portion of the trench portions and the first lifetime region in the second direction.

10. The semiconductor device according to claim 1, wherein
the diode portion has two or more second lifetime regions including the second lifetime region which are spaced apart from each other in the first direction.

11. The semiconductor device according to claim 1, wherein
the second lifetime region is sandwiched between first lifetime regions including the first lifetime region also in a third direction parallel to the upper surface of the semiconductor substrate and perpendicular to the first direction.

12. The semiconductor device according to claim 11, wherein
a width of the second lifetime region in the third direction is 0.2 times or more the thickness of the first lifetime region in the second direction.

13. The semiconductor device according to claim 1, wherein
the width of the second lifetime region in the first direction is greater than or equal to 3% of a diffusion length of charge carriers in the semiconductor substrate.

14. The semiconductor device according to claim 1, wherein
the thickness of the first lifetime region in the second direction is smaller than a thickness of the drift region in the second direction.

15. The semiconductor device according to claim 1, wherein
the width of the second lifetime region in the first direction is 0.2 times or more the thickness of the first lifetime region in the second direction perpendicular to the upper surface of the semiconductor substrate.

16. The semiconductor device according to claim 6, wherein
a width of the first lifetime region is greater than a width of a mesa portion sandwiched between the trench portions which are adjacent to each other.

17. The semiconductor device according to claim 1, wherein
the first lifetime region contains hydrogen.

18. The semiconductor device according to claim 1, wherein
the first lifetime region contains helium.

19. The semiconductor device according to claim 5, wherein
the first lifetime region is provided in the diode portion and the transistor portion,
a ratio of an area of the second lifetime region enclosed by the first lifetime region to an area of the first lifetime region in the transistor portion is smaller than a ratio of an area of the second lifetime region enclosed by the first lifetime region to an area of the first lifetime region in the diode portion.

20. The semiconductor device according to claim 5, wherein
the second lifetime region is provided in the first lifetime region of the diode portion, and
the second lifetime region is not provided in the first lifetime region of the transistor portion.

21. The semiconductor device according to claim 1, comprising
a plurality of trench portions which extend in a direction at an angle greater than 0 degree and smaller than 90 degrees with respect to the first direction at the upper surface of the semiconductor substrate.
